(19) United States
(12) Patent Application Publication
(10) Pub. No.: US 2026/0194892 A1
(43) Pub. Date: Jul. 9, 2026

(54) SYSTEM AND METHOD

(71) Applicant: HOMMA Group Corp., Tokyo (JP)

(72) Inventors: Kyosuke INOUE, Tokyo (JP); Shotaro UCHIDA, Tokyo (JP); Yusuke SATO, Tokyo (JP); Hikaru SUGIURA, Tokyo (JP)

(73) Assignee: HOMMA Group Corp., Tokyo (JP)

(21) Appl. No.: 19/553,869

(22) Filed: Mar. 2, 2026

Related U.S. Application Data
(63) Continuation of application No. PCT/JP2023/038316, filed on Oct. 24, 2023.
(60) Provisional application No. 63/541,355, filed on Sep. 29, 2023.

(51) Int. Cl. G05B 19/418; G06F 30/13

(52) U.S. Cl. CPC G05B 19/41885; G06F 30/13; G05B 2219/35061

(57) ABSTRACT

An information processing system includes one or more information processing apparatuses having processing circuitry. The processing circuitry receives, from a first terminal, input specifying an arrangement and usage of a logical device on architectural drawing data of a building, and registers an arrangement position and an operation setting associated with the drawing data. The processing circuitry also receives identification information of a physical device and a hub from a second terminal, registers the identification information, and pairs the physical device with the hub. After installation of the physical device and the hub in the building, a floor plan image showing the arrangement position of the logical device is displayed on a third terminal. When an arrangement position is designated on the floor plan image, identification information read from a physical device or a hub installed at the position is associated with the logical device.

### CROSS-REFERENCE TO RELATED APPLICATIONS

This application is continuation of International Patent Application No. PCT/JP2023/038316, filed Oct. 24, 2023, which is based upon and claims the benefit of priority from U.S. Provisional Patent Application No. 63/541,355, filed Sep. 29, 2023, the entire contents of all of each are incorporated herein by reference.

### FIELD

The present disclosure relates to a system and a method.

### BACKGROUND

There is technology for easily introducing a smart home device to a large-scale building having a plurality of rooms of the same floor plan.

A conventional system aims to expedite the commissioning process, which is the process of associating the physical locations of installed technical devices with logical addresses. In particular, the conventional system relates to the commissioning of lighting, sensors, actuators, and control networks, and describes software that can create reference copies of planned logical devices and logical functions without requiring direct binding to physical devices for redundant sections within a large-scale building or a complex facility.

In the conventional system, an object is to expedite the commissioning process of a building having redundant sections. However, there is a desire to further reduce the labor involved in the series of processes—from the design stage of a property into which a smart home device is introduced, through to construction, setting, and operational verification.

An object of the present disclosure is to reduce the cost, time and effort in the series of processes—from the design stage of a property into which a smart home device is introduced, through to construction, setting, and operational verification.

### BRIEF DESCRIPTION OF THE DRAWINGS

FIG. 1 is a block diagram showing an example of the overall configuration of a system 1.

FIG. 2 is a block diagram showing a configuration example of a first terminal apparatus 10 shown in FIG. 1.

FIG. 3 is a block diagram showing a configuration example of a second terminal apparatus 30 shown in FIG. 1.

FIG. 4 is a block diagram showing a configuration example of a third terminal apparatus 40 shown in FIG. 1.

FIG. 5 shows an example of a functional configuration of a server 20 shown in FIG. 1.

FIG. 6 shows a data structure of a floor plan table 2021.

FIG. 7 shows a data structure of a logical device table 2022.

FIG. 8 shows a data structure of a physical device table 2023.

FIG. 9 shows a data structure of a hub management table 2024.

FIG. 10 shows a data structure of a dwelling unit table 2025.

FIG. 11 shows a data structure of an association table 2026.

FIG. 12 is a schematic diagram showing a flow of the entire processing according to the present disclosure.

FIG. 13 is a flowchart showing an example of the operations of the first terminal apparatus 10 and the server 20 when generating registration information of logical devices.

FIG. 14 is a flowchart showing an example of the operations of the server 20 and the second terminal apparatus 30 when performing the processing for pairing physical devices and hubs.

FIG. 15 is a flowchart showing an example of the operations of the third terminal apparatus 40 and the server 20 when associating physical devices actually installed in a dwelling unit with logical devices arranged on dwelling unit drawing data.

FIG. 16 is a schematic diagram showing an example of information on dwelling units included in a building designated by a third user, which is displayed on the third terminal apparatus 40.

FIG. 17 is a schematic diagram showing an example of a screen displaying a floor plan and a list of logical devices, which is displayed on the third terminal apparatus 40.

FIG. 18 is a schematic diagram showing an example of a screen for receiving an instruction for operation verification of the associated physical devices, which is displayed on the third terminal apparatus 40.

FIG. 19 is a block diagram showing a basic hardware configuration of a computer 90.

### DETAILED DESCRIPTION

In general, according to one embodiment, a system comprises one or more information processing apparatuses, wherein the one or more information processing apparatuses include processing circuitry. The processing circuitry is configured to: receive, from a first terminal, an input of an arrangement of a logical device and an input of a usage of the logical device on architectural drawing data of a specific building; register an arrangement position and operation setting of the logical device based on the architectural drawing data with which the arrangement and usage of the logical device are associated; receive, from a second terminal, identification information of a physical device to be installed in the building and identification information of a hub to be installed in the building, a label that allows identification of the identification information of the physical device being attached to the physical device, and a label that allows identification of the identification information of the hub being attached to the hub; register the identification information of the physical device and the identification information of the hub, and pair the physical device with the hub; after the physical device and the hub are installed in the building, cause a third terminal to display a floor plan image of the building showing the arrangement position of the logical device; when the arrangement position is designated on the floor plan image via the third terminal, cause the third terminal to display a request for a physical device or a hub installed at the arrangement position; and in response to the request, associate the identification information read from the physical device or the hub by the third terminal with the logical device arranged on the floor plan image.

Hereinafter, an embodiment of the present disclosure will be described with reference to the drawings. In the following description, identical parts are denoted by the same reference numeral. Their names and functions are also the same. Therefore, their detailed description will not be repeated.

### <Overview>

The system according to the present embodiment is technology relating to a device setup framework. At the design stage, the system receives a designation of arrangements of logical devices on architectural drawing data of the building, and sets the arrangements and usages of the logical devices. Before shipping physical devices to the building, the system registers physical devices to be installed in the building and performs pairing between the physical devices. After the physical devices are installed in the building, the system associates the physical devices actually installed in the building with logical devices arranged on the architectural drawing data. This reduces the cost and time and effort involved in introducing smart home devices into a building.

In the present embodiment, the physical device refers to a physically existing device such as a lighting fixture, a sensor, a controller, an actuator, a switch, a hub, or the like which may be introduced into a smart home. That is, the physical device is a so-called smart home appliance, which has a unique network address such as an IP address or a MAC address. In addition, the physical device may be adapted to short-range wireless communication such as ZigBee (registered trademark). In the present embodiment, the hub is, for example, a device that manages a plurality of physical devices connected to a network. For example, the hub receives an operation from a user, and controls a corresponding physical device in accordance with the received operation. Further, the hub receives, for example, predetermined data from a physical device and controls a corresponding physical device based on the received data.

In the present embodiment, the logical device refers to an independent device recognized by a program. Logical devices are virtually arranged on architectural drawing data of the building in imitation of the arrangements of physical devices.

In the present embodiment, the architectural drawing data of a building is, for example, data used when a building is constructed. The architectural drawing data is realized by, for example, 3D CAD data, building information modeling (BIM) data, or the like. In the following description, the architectural drawing data of a building may be simply referred to as drawing data.

### <1 Configuration Diagram of Entire System>

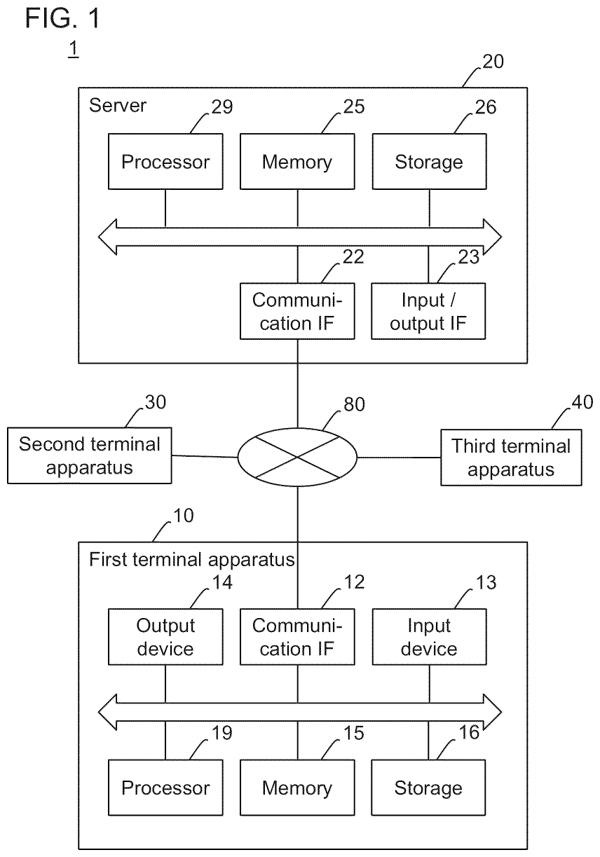

FIG. 1 is a block diagram showing an example of the overall configuration of a system 1. The system 1 shown in FIG. 1 includes, for example, a first terminal apparatus 10, a server 20, a second terminal apparatus 30, and a third terminal apparatus 40. The first terminal apparatus 10, the server 20, the second terminal apparatus 30, and the third terminal apparatus 40 are connected for communication via a network 80, for example.

In the present embodiment, the number of the first terminal apparatuses 10, the number of the second terminal apparatuses 30, and the number of the third terminal apparatuses 40 included in the system 1 may each be one, or may each be a plurality. Further, one terminal apparatus may realize the functions of at least two of the first terminal apparatus 10, the second terminal apparatus 30, and the third terminal apparatus 40.

In the present embodiment, a collection of a plurality of apparatuses may be considered as one server. How to distribute a plurality of functions required to realize the server 20 according to the present embodiment to one or more pieces of hardware can be determined as appropriate in consideration of the processing capability of each piece of hardware and/or the specifications required for the server 20, etc.

The first terminal apparatus 10 shown in FIG. 1 is, for example, an information processing apparatus that is operated by a staff member when determining the arrangements and settings of physical devices in a building. The first terminal apparatus 10 determines the arrangements of physical devices by, for example, arranging logical devices on architectural drawing data of the building in response to an operation by the staff member. In addition, the first terminal apparatus 10 sets the usages of the logical devices arranged on the architectural drawing data in response to an operation by the staff member, for example. In the present embodiment, the physical devices installed in the smart home automatically operate based on the result of sensing of the resident or the environment by a sensor or the like without receiving an operation from the resident, for example. The setting of the usage in the present embodiment refers to, for example, setting how to operate the physical device and how to set the ambience in the building.

The first terminal apparatus 10 is realized by, for example, a mobile terminal such as a smartphone or a tablet. The first terminal apparatus 10 may be a stationary personal computer (PC) or a laptop PC. The first terminal apparatus 10 may be a head mount display (HMD), or a wearable terminal such as a wristwatch type terminal.

The first terminal apparatus 10 includes a communication interface (IF) 12, an input device 13, an output device 14, a memory 15, a storage 16, and a processor 19. The input device 13 is a device (e.g., a touch panel, a touch pad, a pointing device such as a mouse, a keyboard, etc.) for receiving an input operation from the user. The output device 14 is a device (e.g., a display, a speaker, etc.) for presenting information to the user.

The second terminal apparatus 30 shown in FIG. 1 is, for example, an information processing apparatus that is operated by a staff member when pairing physical devices to be installed in a building before sending the physical devices to the building. For example, in response to an operation by the staff member, the second terminal apparatus 30 acquires information on the physical devices to be installed in the building, performs a predetermined process, and performs pairing setting between the physical devices. The second terminal apparatus 30 is realized by, for example, a stationary personal computer (PC) or a laptop PC. The second terminal apparatus 30 may be a mobile terminal such as a smartphone or a tablet. The second terminal apparatus 30 may be a head mount display (HMD), or a wearable terminal such as a wristwatch type terminal.

The third terminal apparatus 40 shown in FIG. 1 is an information processing apparatus operated by the staff member when physical devices actually installed in a building are associated with virtually arranged logical devices. For example, in response to an operation by the staff member, the third terminal apparatus 40 associates physical devices installed in the building with logical devices set on the architectural drawing data. In addition, the third terminal apparatus 40, for example, tests whether or not the associated physical devices normally operate in response to an operation by the staff member. The third terminal apparatus 40 may be realized by a mobile terminal such as a smartphone or a tablet. The third terminal apparatus 40 may be a stationary personal computer (PC) or a laptop PC. The third terminal apparatus 40 may be a head mount display (HMD), or a wearable terminal such as a wristwatch type terminal.

The server 20 shown in FIG. 1 is an information processing apparatus that accepts connections from the first terminal apparatus 10, the second terminal apparatus 30, the third terminal apparatus 40, and specific physical devices, and executes processing requested by each apparatus.

The server 20 is, for example, an information processing apparatus realized by a computer connected to the network 80. As shown in FIG. 1, the server 20 includes a communication IF 22, an input/output IF 23, a memory 25, a storage 26, and a processor 29. The processor 29 is an example of processing circuitry. The input/output IF 23 functions as an interface with an input device for receiving an input operation from the user and an output device for outputting information to the user.

Each information processing apparatus is constituted by a computer including an arithmetic device and a storage device. A basic hardware configuration of the computer and a basic functional configuration of the computer realized by the hardware configuration will be described later. For each of the first terminal apparatus 10, the server 20, the second terminal apparatus 30, and the third terminal apparatus 40, descriptions overlapping with the following descriptions of the basic hardware configuration of the computer and the basic functional configuration of the computer will be omitted.

### <1.1 Configuration of First Terminal Apparatus>

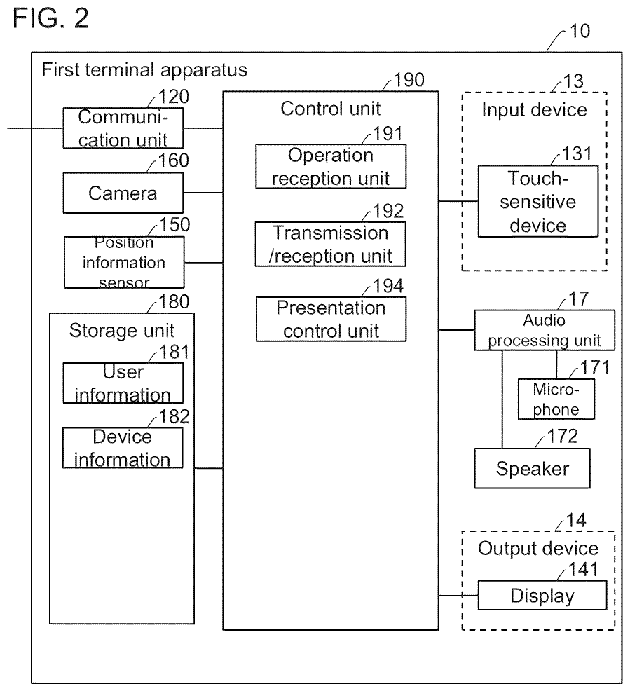

FIG. 2 is a block diagram showing a configuration example of the first terminal apparatus 10 shown in FIG. 1. As shown in FIG. 2, the first terminal apparatus 10 includes a communication unit 120, an input device 13, an output device 14, an audio processing unit 17, a microphone 171, a speaker 172, a camera 160, a position information sensor 150, a storage unit 180, and a control unit 190. The blocks included in the first terminal apparatus 10 are electrically connected by a bus or the like.

The communication unit 120 performs processes such as modulation and demodulation processes for the first terminal apparatus 10 to communicate with other apparatuses. The communication unit 120 performs a transmission process on a signal generated by the control unit 190 and transmits the signal to the outside (for example, the server 20). The communication unit 120 performs a reception process on a signal received from outside, and outputs the signal to the control unit 190.

The input device 13 is a device for the user who operates the first terminal apparatus 10 to input an instruction or information. The input device 13 is realized by, for example, a touch-sensitive device 131 that inputs an instruction when touched on the operation surface. When the first terminal apparatus 10 is a PC or the like, the input device 13 may be realized by a keyboard, a mouse, or the like. The input device 13 converts an instruction input from the user into an electric signal, and outputs the electric signal to the control unit 190. It should be noted that the input device 13 may include, for example, a reception port that receives an electric signal input from an external input device.

The output device 14 is a device for presenting information to the user who operates the first terminal apparatus 10. The output device 14 is realized by, for example, a display 141 or the like. The display 141 displays data according to the control of the control unit 190. The display 141 is realized by, for example, a liquid crystal display (LCD) or an organic electro-luminescence (EL) display.

The audio processing unit 17 performs, for example, digital-to-analog conversion processing of an audio signal. The audio processing unit 17 converts a signal provided by the microphone 171 into a digital signal and provides the converted signal to the control unit 190. The audio processing unit 17 also provides an audio signal to the speaker 172. The audio processing unit 17 is realized by, for example, a processor for audio processing. The microphone 171 receives an audio input and provides an audio signal corresponding to the audio input to the audio processing unit 17. The speaker 172 converts the audio signal provided from the audio processing unit 17 into audio and outputs the audio to the outside of the first terminal apparatus 10.

The camera 160 is a device that receives light with a light receiving element and outputs it as an imaging signal.

The position information sensor 150 is a sensor for detecting the position of the first terminal apparatus 10, and is, for example, a global positioning system (GPS) module. The GPS module is a reception device used in a satellite positioning system. The satellite positioning system receives signals from at least three or four satellites, and detects the current position of the first terminal apparatus 10 equipped with the GPS module based on the received signals. The position information sensor 150 may detect the current position of the first terminal apparatus 10 from the position of the wireless base station to which the first terminal apparatus 10 is connected.

The storage unit 180 is realized by, for example, the memory 15, the storage 16, and the like, and stores data and programs used by the first terminal apparatus 10. The storage unit 180 stores, for example, user information 181 and device information 182.

The user information 181 includes, for example, information on users who use the first terminal apparatus 10. The information on users includes, for example, a user ID.

The device information 182 includes, for example, information on physical devices that can be installed in the building. The information on physical devices includes, for example, a device type, a device name, a manufacturing company, and the like.

The control unit 190 is realized by the processor 19 reading a program stored in the storage unit 180 and executing instructions included in the program. The control unit 190 controls the operation of the first terminal apparatus 10. The control unit 190 operates in accordance with the program to perform the functions as an operation reception unit 191, a transmission/reception unit 192, and a presentation control unit 194.

The operation reception unit 191 performs a process of receiving an instruction or information input from the input device 13. Specifically, for example, the operation reception unit 191 receives an instruction or information input from the touch-sensitive device 131 or the like. More specifically, for example, the operation reception unit 191 receives an operation for adjusting the arrangements of the logical devices with respect to the architectural drawing data. Further, for example, the operation reception unit 191 receives a selection of a type of logical device. Further, for example, the operation reception unit 191 receives an operation for setting the usages of logical devices arranged on the architectural drawing data. The architectural drawing data on which the arrangements and usages of the logical devices are set is so-called master data in the subsequent processing.

In addition, the operation reception unit 191 receives a voice instruction input from the microphone 171. Specifically, for example, the operation reception unit 191 receives an audio signal input from the microphone 171 and converted into a digital signal by the audio processing unit 17. The operation reception unit 191 acquires an instruction from the user by, for example, analyzing the received audio signal and extracting a predetermined noun.

The transmission/reception unit 192 performs a process for the first terminal apparatus 10 to transmit and receive data to and from an external apparatus such as the server 20 in accordance with a communication protocol. Specifically, for example, the transmission/reception unit 192 transmits information input by the user or an instruction from the user to the server 20. The transmission/reception unit 192 also receives information provided from the server 20.

The presentation control unit 194 controls the output device 14 to present specific information to the user. Specifically, for example, the presentation control unit 194 acquires the architectural drawing data of the building, and causes the display 141 to display an image based on the acquired architectural drawing data. The architectural drawing data of the building may be stored in the first terminal apparatus 10, may be stored in the server 20, or may be stored in another server (not shown) that manages architectural information. Further, the presentation control unit 194 causes the speaker 172 to output information for setting logical devices on the architectural drawing data.

### <1.2 Configuration of Second Terminal Apparatus>

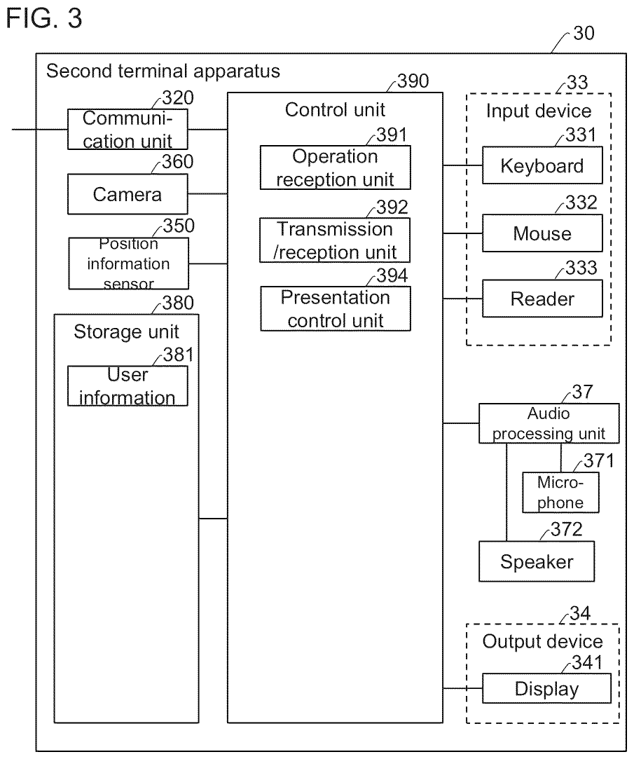

FIG. 3 is a block diagram showing a configuration example of the second terminal apparatus 30 shown in FIG. 1. As shown in FIG. 2, the second terminal apparatus 30 includes a communication unit 320, an input device 33, an output device 34, an audio processing unit 37, a microphone 371, a speaker 372, a camera 360, a position information sensor 350, a storage unit 380, and a control unit 390. The blocks included in the second terminal apparatus 30 are electrically connected by a bus or the like.

The communication unit 320 performs processes such as modulation and demodulation processes for the second terminal apparatus 30 to communicate with other apparatuses. The communication unit 320 performs a transmission process on a signal generated by the control unit 390 and transmits the signal to the outside (for example, the server 20). The communication unit 320 performs a reception process on a signal received from outside, and outputs the signal to the control unit 390.

The input device 33 is a device for inputting an instruction or information to the user who operates the second terminal apparatus 30. The input device 33 is realized by, for example, a keyboard 331, a mouse 332, and a reader 333. The reader 333 is realized by, for example, an optical reader. The reader 333 reads data from, for example, a two-dimensional barcode or a code such as a barcode. The input device 33 may be realized by a touch-sensitive device or the like. The input device 33 converts an instruction input from the user into an electric signal, and outputs the electric signal to the control unit 390. It should be noted that the input device 33 may include, for example, a reception port that receives an electric signal input from an external input device.

The output device 34 is a device for presenting information to the user who operates the second terminal apparatus 30. The output device 34 is realized by, for example, a display 341 or the like. The display 341 displays data according to the control of the control unit 390. The display 341 is realized by, for example, a liquid crystal display (LCD) or an organic electro-luminescence (EL) display. The output device 34 may be an output port for outputting information to the outside. The output port is connected to, for example, a printer, and causes the printer to print a specific image.

The audio processing unit 37 performs, for example, digital-to-analog conversion processing of an audio signal. The audio processing unit 37 converts a signal provided by the microphone 371 into a digital signal and provides the converted signal to the control unit 390. The audio processing unit 37 also provides an audio signal to the speaker 372. The audio processing unit 37 is realized by, for example, a processor for audio processing. The microphone 371 receives an audio input and provides an audio signal corresponding to the audio input to the audio processing unit 37. The speaker 372 converts the audio signal provided from the audio processing unit 37 into audio and outputs the audio to the outside of the second terminal apparatus 30.

The camera 360 is a device that receives light with a light receiving element and outputs it as an imaging signal.

The position information sensor 350 is a sensor for detecting the position of the second terminal apparatus 30, and is, for example, a global positioning system (GPS) module. The position information sensor 350 may detect the current position of the second terminal apparatus 30 from the position of the wireless base station to which the second terminal apparatus 30 is connected.

The storage unit 380 is realized by, for example, the memory 35, the storage 36, and the like, and stores data and programs used by the second terminal apparatus 30. The storage unit 380 stores user information 381.

The user information 381 includes, for example, information on users who use the second terminal apparatus 30. The information on users includes, for example, a user ID.

The control unit 390 is realized by the processor 39 reading a program stored in the storage unit 380 and executing instructions included in the program. The control unit 390 controls the operation of the second terminal apparatus 30. The control unit 390 operates in accordance with the program to perform the functions as an operation reception unit 391, a transmission/reception unit 392, and a presentation control unit 394.

The operation reception unit 391 performs a process of receiving an instruction or information input from the input device 33. Specifically, for example, the operation reception unit 391 receives an instruction or information input from a keyboard 331 or the like. More specifically, for example, the operation reception unit 391 receives information on physical devices to be installed in the building, which is read by the reader 333. Further, for example, the operation reception unit 391 receives an operation for pairing the physical devices whose information is read.

In addition, the operation reception unit 391 receives a voice instruction input from the microphone 371. Specifically, for example, the operation reception unit 391 receives an audio signal input from the microphone 371 and converted into a digital signal by the audio processing unit 37. The operation reception unit 391 acquires an instruction from the user by, for example, analyzing the received audio signal and extracting a predetermined noun.

The transmission/reception unit 392 performs a process for the second terminal apparatus 30 to transmit and receive data to and from an external apparatus such as the server 20 in accordance with a communication protocol. Specifically, for example, the transmission/reception unit 392 transmits information input by the user or an instruction from the user to the server 20. The transmission/reception unit 392 also receives information provided from the server 20. The transmission/reception unit 392 also reads information from the physical devices using a communication protocol such as Bluetooth (registered trademark) or Wi-Fi (registered trademark). Alternatively, the transmission/reception unit 392 may read information from the physical devices using short-range wireless communication.

The presentation control unit 394 controls the output device 34 to present specific information to the user. Specifically, for example, the presentation control unit 394 causes the display 341 to display an image for pairing the physical devices. The presentation control unit 394 also causes the speaker 372 to output information for pairing the physical devices.

### <1.3 Configuration of Third Terminal Apparatus>

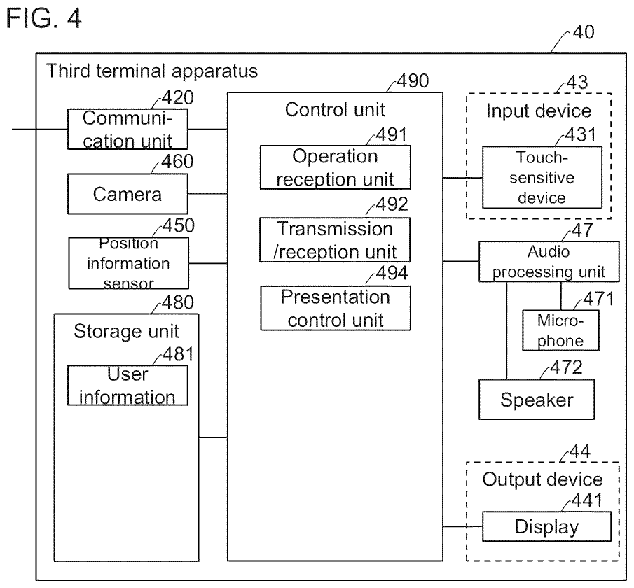

FIG. 4 is a block diagram showing a configuration example of the third terminal apparatus 40 shown in FIG. 1. As shown in FIG. 4, the third terminal apparatus 40 includes a communication unit 420, an input device 43, an output device 44, an audio processing unit 47, a microphone 471, a speaker 472, a camera 460, a position information sensor 450, a storage unit 480, and a control unit 490. The blocks included in the third terminal apparatus 40 are electrically connected by a bus or the like.

The communication unit 420 performs processes such as modulation and demodulation processes for the third terminal apparatus 40 to communicate with other apparatuses. The communication unit 420 performs a transmission process on a signal generated by the control unit 490 and transmits the signal to the outside (for example, the server 20). The communication unit 420 performs a reception process on a signal received from outside, and outputs the signal to the control unit 490.

The input device 43 is a device for inputting an instruction or information to the user who operates the third terminal apparatus 40. The input device 43 is realized by, for example, a touch-sensitive device 431 or the like. When the third terminal apparatus 40 is a PC or the like, the input device 43 may be realized by a keyboard, a mouse, or the like. The input device 43 converts an instruction input from the user into an electric signal, and outputs the electric signal to the control unit 490. It should be noted that the input device 43 may include, for example, a reception port that receives an electric signal input from an external input device.

The output device 44 is a device for presenting information to the user who operates the third terminal apparatus 40. The output device 44 is realized by, for example, a display 441 or the like. The display 441 displays data according to the control of the control unit 490. The display 441 is realized by, for example, a liquid crystal display (LCD) or an organic electro-luminescence (EL) display.

The audio processing unit 47 performs, for example, digital-to-analog conversion processing of an audio signal. The audio processing unit 47 converts a signal provided by the microphone 471 into a digital signal and provides the converted signal to the control unit 490. The audio processing unit 47 also provides an audio signal to the speaker 472. The audio processing unit 47 is realized by, for example, a processor for audio processing. The microphone 471 receives an audio input and provides an audio signal corresponding to the audio input to the audio processing unit 47. The speaker 472 converts the audio signal provided from the audio processing unit 47 into audio and outputs the audio to the outside of the third terminal apparatus 40.

The camera 460 is a device that receives light with a light receiving element and outputs it as an imaging signal.

The position information sensor 450 is a sensor for detecting the position of the third terminal apparatus 40, and is, for example, a global positioning system (GPS) module. The position information sensor 450 may detect the current position of the third terminal apparatus 40 from the position of the wireless base station to which the third terminal apparatus 40 is connected.

The storage unit 480 is realized by, for example, the memory 45, the storage 46, and the like, and stores data and programs used by the third terminal apparatus 40. The storage unit 480 stores user information 481.

The user information 481 includes, for example, information on users who use the third terminal apparatus 40. The information on users includes, for example, a user ID.

The control unit 490 is realized by the processor 49 reading a program stored in the storage unit 480 and executing instructions included in the program. The control unit 490 controls the operation of the third terminal apparatus 40. The control unit 490 operates in accordance with the program to perform the functions as an operation reception unit 491, a transmission/reception unit 492, and a presentation control unit 494.

The operation reception unit 491 performs a process of receiving an instruction or information input from the input device 43. Specifically, for example, the operation reception unit 491 receives an instruction or information input from the touch-sensitive device 431 or the like. More specifically, for example, the operation reception unit 491 receives an operation for associating physical devices with logical devices. Further, for example, the operation reception unit 491 receives an operation for checking the operations of the physical devices associated with logical devices.

In addition, the operation reception unit 491 receives a voice instruction input from the microphone 471. Specifically, for example, the operation reception unit 491 receives an audio signal input from the microphone 471 and converted into a digital signal by the audio processing unit 47. The operation reception unit 491 acquires an instruction from the user by, for example, analyzing the received audio signal and extracting a predetermined noun.

The operation reception unit 491 receives an instruction input from the camera 460. Specifically, for example, the operation reception unit 491 receives information obtained by decoding an image captured by the camera 460. The operation reception unit 491 recognizes the installed physical devices based on the received information, for example.

The transmission/reception unit 492 performs a process for the third terminal apparatus 40 to transmit and receive data to and from an external apparatus such as the server 20 in accordance with a communication protocol. Specifically, for example, the transmission/reception unit 492 transmits information input by the user or an instruction from the user to the server 20. The transmission/reception unit 492 also receives information provided from the server 20.

The presentation control unit 494 controls the output device 44 to present specific information to the user. Specifically, for example, the presentation control unit 494 causes the display 441 to display an image for associating the physical devices installed in the building with logical devices. Further, the presentation control unit 494 causes the display 441 to display an image for checking the operations of the physical devices associated with logical devices. Further, the presentation control unit 494 causes the speaker 472 to output information for associating the physical devices installed in the building with logical devices.

### <1.4 Functional Configuration of Server>

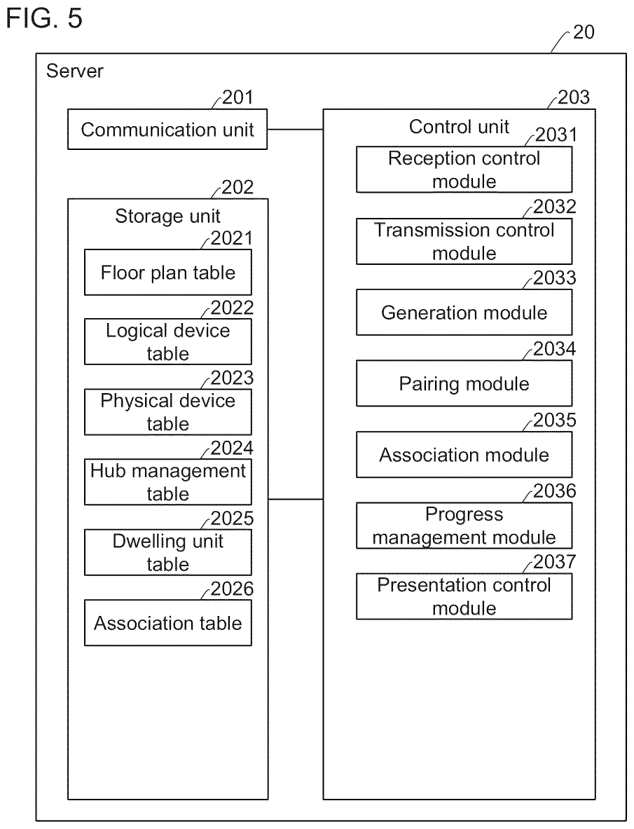

FIG. 5 is a diagram showing an example of the functional configuration of the server 20. As shown in FIG. 5, the server 20 performs functions as a communication unit 201, a storage unit 202, and a control unit 203.

The communication unit 201 performs a process for the server 20 to communicate with an external apparatus.

The storage unit 202 includes, for example, a floor plan table 2021, a logical device table 2022, a physical device table 2023, a hub management table 2024, a dwelling unit table 2025, and an association table 2026. The tables stored in the storage unit 202 are not limited thereto. In the storage unit 202, for example, a table for storing information on buildings and a table for storing information on users may be stored.

The floor plan table 2021 stores information related to floor plans. Details will be described later.

The logical device table 2022 is a table for storing information related to logical devices. Details will be described later.

The physical device table 2023 is a table for storing information related to physical devices. Details will be described later.

The hub management table 2024 is a table for storing information related to hubs. Details will be described later.

The dwelling unit table 2025 is a table for storing information related to dwelling units. Details will be described later.

The association table 2026 is a table for storing information related to the association between logical devices and physical devices. Details will be described later.

The control unit 203 is realized by the processor 29 reading a program stored in the storage unit 202 and executing instructions included in the program. The control unit 203 operates in accordance with the program to function as a reception control module 2031, a transmission control module 2032, a generation module 2033, a pairing module 2034, an association module 2035, a progress management module 2036, and a presentation control module 2037.

The reception control module 2031 controls a process for the server 20 to receive a signal from an external apparatus in accordance with a communication protocol. Specifically, for example, the reception control module 2031 receives, from the first terminal apparatus 10, information on the logical devices arranged on the architectural drawing data. Further, for example, the reception control module 2031 receives, from the second terminal apparatus 30 or the hub, information on the physical devices for which pairing has been completed. Moreover, for example, the reception control module 2031 receives, from the third terminal apparatus 40, information on the associated physical devices and logical devices. Moreover, for example, the reception control module 2031 receives, from the third terminal apparatus 40, a result of the checking processing on the physical devices associated with the logical devices.

The transmission control module 2032 controls a process for the server 20 to transmit a signal to an external apparatus in accordance with a communication protocol. Specifically, for example, the transmission control module 2032 transmits information for ordering physical devices to be installed in the building to the ordering destination of the physical devices based on the logical devices arranged on the architectural drawing data. Moreover, for example, the transmission control module 2032 transmits, to the third terminal apparatus 40, information on the logical devices arranged on the architectural drawing data.

The generation module 2033 generates an operation mode of each physical device installed in the building based on the architectural drawing data on which the logical device is arranged. Specifically, the generation module 2033 acquires the type of the logical device, the position coordinates at which the logical device is arranged, the information on the building, and the usage set for the logical device, based on the architectural drawing data. That is, the generation module 2033 converts the architectural drawing data into logical information that can be used in subsequent processing. Hereinafter, the logical information converted from the architectural drawing data is referred to as registration information. At this time, the generation module 2033 may select physical devices to be actually installed and include the physical devices in the logical information. In the registration information, for example, identification information of the logical device, the type of the logical device, the name of the logical device, information on the building, position information, and the like are associated.

Further, the generation module 2033 calculates how to operate the physical device based on the registration information. For example, the generation module 2033 calculates the time zone of operation, the ambience to be realized (behavior, time zone of operation of each device), the mode of activity, and the like based on the logical information.

The generation module 2033 generates a floor plan image based on the architectural drawing data on which the logical devices are arranged. The floor plan image is, for example, a two-dimensional image of a floor showing logical devices arranged with respect to the architectural drawing data.

The pairing module 2034 controls processing related to pairing of physical devices based on the registration information. Specifically, for example, the pairing module 2034 assigns a specific floor plan to a hub, which is an example of the physical device. The pairing module 2034 acquires information on a physical device to be installed in a building, and registers the acquired information. The information on a physical device to be installed in a building is, for example, a MAC address set for the physical device. When a predetermined code is attached to the physical device, the pairing module 2034 acquires information read from the code by the reader 333 as information on the physical device. When a specific code is not attached to the physical device, the pairing module 2034 acquires information read from the physical device using a predetermined communication protocol as information on the physical device. Upon acquiring the information on the physical device from the physical device, the pairing module 2034 generates a specific code based on the acquired information. The pairing module 2034 causes, for example, a predetermined printer to output information on the generated code.

The association module 2035 associates a logical device arranged in the architectural drawing data with a physical device actually installed in the building. Specifically, for example, the association module 2035 acquires identification information of the physical device installed at the position corresponding to the logical device arranged at a specific position on the architectural drawing data. The association module 2035 associates the acquired identification information of the physical device with identification information of the logical device arranged at the corresponding position. For example, the association module 2035 associates the ID of the physical device installed at a specific position in the building with the ID of the logical device arranged at the corresponding position on the architectural drawing data.

In addition, the association module 2035 performs processing for verifying the operation of each physical device associated with a logical device. Specifically, the association module 2035 transmits an instruction to operate the physical device associated with the logical device, to the hub paired with the physical device. The hub transmits a signal to the physical device to operate the physical device based on the instruction. Whether or not the physical device has operated is checked by, for example, the user who operates the third terminal apparatus 40. The association module 2035 receives an input of information on whether or not the physical device has normally operated, and stores the information in the storage unit 202 as a verification result.

The progress management module 2036 manages the progress of associating logical devices with physical devices. Specifically, it manages unassociated logical devices, associated logical devices, logical devices that are associated but have failed in the verification, or logical devices that have been verified. For example, the progress management module 2036 stores information on logical devices in the storage unit 202 so that unassociated logical devices and associated logical devices are distinguishable. In addition, the progress management module 2036 may store information on logical devices in the storage unit 202 so that logical devices that are associated but have failed in the verification and logical devices that have been verified are distinguishable. The progress management module 2036 updates, at a predetermined timing, the information on the progress of associating logical devices, which is stored in the storage unit 202.

In addition, the progress management module 2036 may aggregate the number of unassociated logical devices, the number of associated logical devices, the number of logical devices that are associated but have failed in the verification, or the number of logical devices that have been verified, for each predetermined group, and transmit the aggregation result to another information processing apparatus. For example, the progress management module 2036 may aggregate the number of unassociated logical devices, the number of associated logical devices, the number of logical devices that are associated but have failed in the verification, or the number of logical devices that have been verified for each unit of one or more dwelling units, each unit of one or more floors, or each unit of one or more buildings, and transmit the aggregation result to another information processing apparatus.

The presentation control module 2037 presents the information extracted from the storage unit 202 to the user. Specifically, for example, the presentation control module 2037 presents, to the user, information to be referred to when logical devices arranged on the architectural drawing data are associated with physical devices actually installed. The presentation control module 2037 causes the display 441 of the third terminal apparatus 40 to display, for example, a floor plan image.

### <2 Data Structure>

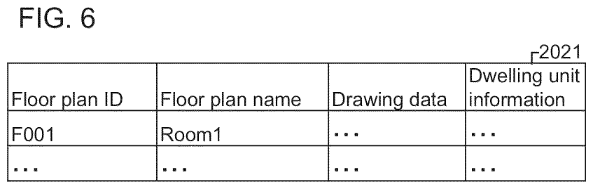

FIG. 6 to FIG. 11 are diagrams showing data structures of the tables stored in the server 20. Note that FIG. 6 to FIG. 11 are examples and do not exclude data that are not described. Even data described in the same table may be stored in separate storage areas in the storage unit 202.

FIG. 6 shows a data structure of the floor plan table 2021. The floor plan table 2021 shown in FIG. 6 is a table having columns of floor plan name, drawing data, and dwelling unit information with a floor plan ID as a primary key.

The floor plan ID is an item for storing an ID for identifying each floor plan. The drawing data is an item for storing architectural drawing data of the relevant floor plan. The architectural drawing data includes, for example, information on at least one of a position, a type, and an operation setting of a logical device arranged on the drawing data. The item “drawing data” may store reference information (link) to a data file located at another location. The dwelling unit information is an item for storing information on dwelling units constructed based on the floor plan. The dwelling unit information may include, for example, at least one of a building name, a building address, the number of dwelling units to which the floor plan is applied, and a room number of the dwelling unit to which the floor plan is applied.

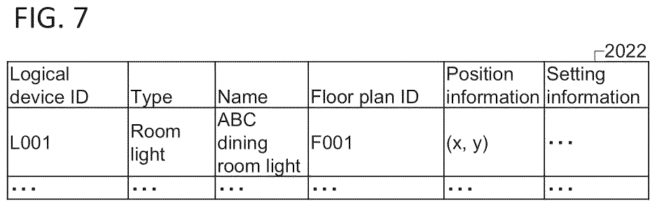

FIG. 7 shows a data structure of the logical device table 2022. The logical device table 2022 shown in FIG. 7 is a table having columns of type, name, floor plan ID, position information, and setting information with a logical device ID as a primary key.

The logical device ID is an item for storing the ID for identifying each logical device. The type is an item for storing the type of the logical device. As the type, for example, a character string indicating the type of the device, such as sensor, light, or switch, may be stored. The name is an item for storing the name of the logical device. As the name, for example, a character string indicating the product name of the logical device may be stored. The floor plan ID stores a floor plan ID of the floor plan on which the logical device is arranged. The position information is an item for storing a position on the floor plan where the logical device is arranged. The item “position information” stores, for example, the position coordinates on the floor plan where the logical device is arranged.

The setting information is an item for storing information on the operation setting of the logical device. The item “setting information” may store information on the operation setting based on an input to the device by the user. The input by the user includes, for example, an input through direct operation of a button, a switch, or the like of the device, a voice input, an input through operation of a remote control device, and the like.

The item “setting information” may store information on the operation setting based on the state of the external environment of the device. The external environment may include time. The item “setting information” stores, for example, a setting for performing a predetermined operation when triggered by events such as reaching a predetermined time.

The external environment may also include temperature. The device related to the item “setting information” may acquire a temperature measured by a predetermined sensor. The sensor may acquire the temperature inside the dwelling unit or may acquire the temperature outside the dwelling unit. The item “setting information” stores, for example, a setting for performing a predetermined operation when triggered by events, such as the temperature acquired by the sensor reaching a predetermined temperature.

The external environment may also include humidity. The device related to the item “setting information” may acquire a humidity measured by a predetermined sensor. The sensor may acquire the humidity inside the dwelling unit or acquire the humidity outside the dwelling unit. The item “setting information” stores, for example, a setting for performing a predetermined operation when triggered by events, such as the humidity acquired by the sensor reaching a predetermined humidity.

The external environment may also include brightness. The device related to the item “setting information” may acquire a brightness measured by a predetermined sensor. The sensor may acquire the brightness inside the dwelling unit, or may acquire the brightness outside the dwelling unit. The item “setting information” stores, for example, a setting for performing a predetermined operation when triggered by events, such as the brightness acquired by the sensor reaching a predetermined brightness.

The external environment may also include information on movement. The information on movement is, for example, information on a change in temperature distribution in a space due to movement of a person. The device related to the item “setting information” may acquire information on an operation detected by a predetermined sensor. The sensor may detect the movement inside the dwelling unit or detect the movement outside the dwelling unit. The item “setting information” stores, for example, a setting for performing a predetermined operation when triggered by events, such as the sensor detecting a predetermined movement.

The item “setting information” may store information on operation setting based on the operation of another device. The item “setting information” stores, for example, a setting for performing a predetermined operation in conjunction with another device performing a predetermined operation.

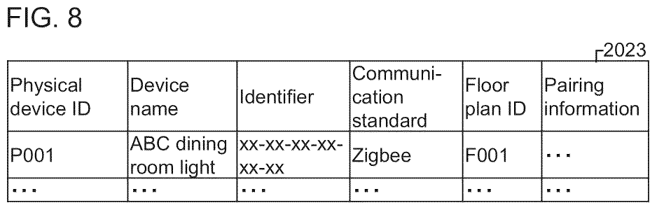

FIG. 8 shows a data structure of the physical device table 2023. The physical device table 2023 shown in FIG. 8 is a table having columns of type, name, identification information, communication standard, and pairing information with a physical device ID as a primary key.

The physical device ID is an item for storing an ID for identifying a physical device. The type is an item for storing the type of the physical device. As the type, for example, a character string indicating the type of the device, such as sensor, light, or switch, may be stored. The name is an item for storing the name of the physical device. As the name, for example, a character string indicating the product name of the physical device may be stored. The identifier is an item for storing an identifier assigned to the physical device. As the identifier, for example, information on the physical address of the physical device may be stored. The communication standard is an item for storing information for identifying a communication standard used when the physical device performs communication. As the communication standard, for example, a character string indicating the name of the communication standard of the physical device, such as Bluetooth (registered trademark) or Zigbee (registered trademark), may be stored. The pairing information is an item for storing information on another device paired with the physical device. As the pairing information, for example, information for identifying a hub paired with the physical device may be stored. As the pairing information, for example, at least one of the hub ID and the identifier of the hub paired with the physical device may be stored. The pairing is not limited to pairing between a physical device and a hub, and physical devices may be paired with each other. Specifically, for example, lighting devices may be paired.

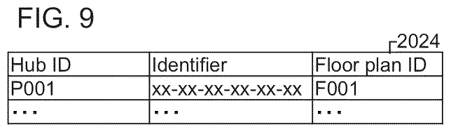

FIG. 9 shows a data structure of the hub management table 2024. The hub management table 2024 shown in FIG. 9 is a table having columns of identifier and floor plan ID with a hub ID as a primary key.

The hub ID is an item for storing an ID for identifying a hub for operating the physical device connected thereto. The identifier is an item for storing an identifier assigned to the hub. As the identifier, for example, information on the physical address of the hub may be stored. The floor plan ID is an item for storing the floor plan ID of a floor plan associated with the hub.

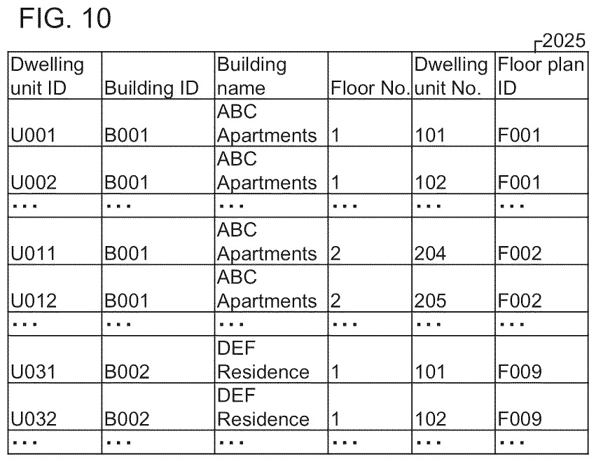

FIG. 10 shows a data structure of the dwelling unit table 2025. The dwelling unit table 2025 shown in FIG. 10 is a table having columns of building ID, building name, floor number, dwelling unit number, and floor plan ID with a dwelling unit ID as a primary key.

The dwelling unit ID is an item for storing an ID for identifying a dwelling unit. The building ID is an item for storing a building ID of the building provided with the dwelling unit. It should be noted that the building ID is an ID for identifying a building in a building table (not shown) for managing building information. The building name is an item for storing a building name of the building provided with the dwelling unit. The floor is an item for storing a floor number at which the dwelling unit is located in the building. The dwelling unit number is an item for storing a number assigned to the dwelling unit. The floor plan ID is an item for storing a floor plan ID of a floor plan associated with the dwelling unit.

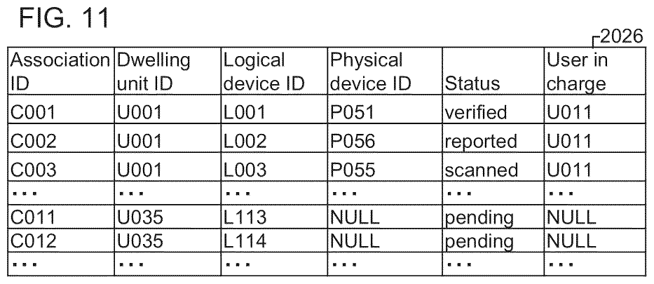

FIG. 11 shows a data structure of the association table 2026. The association table 2026 shown in FIG. 11 is a table having columns of dwelling unit ID, logical device ID, physical device ID, status, and user in charge with an association ID as a primary key. The association table 2026 may store information on the content of the failure of the device to be associated.

The association ID is an item for storing an ID for identifying the association. The dwelling unit ID is an item for storing an ID for identifying a dwelling unit. The logical device ID is an item for storing an ID for identifying a logical device. The physical device ID is an item for storing an ID for identifying a physical device. When the association has not been performed yet, blank, null, or other information indicating that the association has not been performed is stored as the physical device ID. The status is an item for storing information on the progress status of the association processing. Specifically, the status stores information for identifying whether the association processing is started, in progress, or completed. As the status, for example, information indicating any of an unassociated state, an associated state, and a state in which the association has been performed but a failure has occurred in verification of the operation, may be stored. In the present disclosure, stored as the status is information indicating one of the following states: an not-yet-started state where association has not yet started; a scanned state where the code of the physical device has been read and association has been performed; a reported state where a failure in the verification of the operation has been reported; and a verified state where the verification of the operation has been completed. The user in charge is an item for storing the user ID of the user in charge of the operation of the terminal related to the association.

### <3 Operation>

Operation of the first terminal apparatus 10, the server 20, the second terminal apparatus 30, and the third terminal apparatus 40 will be described.

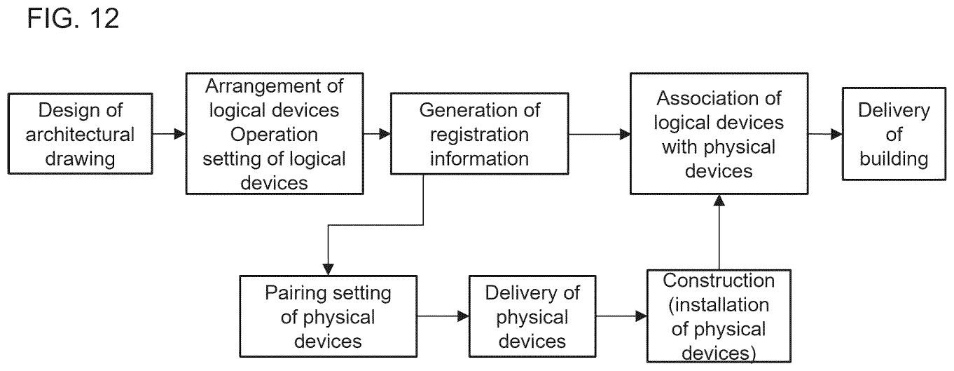

FIG. 12 is a schematic diagram showing a flow of the processing according to the present disclosure.

As shown in FIG. 12, the user operates a specific terminal to design an architectural drawing of a building. In accordance with the user operation, the first terminal apparatus 10 arranges logical devices on the drawing data and performs operation setting of the logical devices. The server 20 generates registration information based on the drawing data, the arrangements of logical devices, and the operation setting of the logical devices.

The second terminal apparatus 30 acquires the registration information from the server 20. Before the physical devices to be installed in the building are delivered to the building, the second terminal apparatus 30 performs pairing setting of the physical devices in accordance with the registration information generated at the design stage. The server 20 registers the physical devices to be installed in the building. The physical devices for which the pairing setting has been performed are delivered to the construction site.

The delivered physical devices are installed at the installation locations in accordance with the floor plan of the building.

The third terminal apparatus 40 acquires the registration information and the floor plan image from the server 20. Based on the information of the installed physical devices transmitted from the third terminal apparatus 40, the server 20 associates the logical devices arranged on the drawing data with the physical devices actually installed in the building.

After the association work is completed for all physical devices that need to be associated, the building is delivered to the client.

### (Generation Processing of Registration Information)

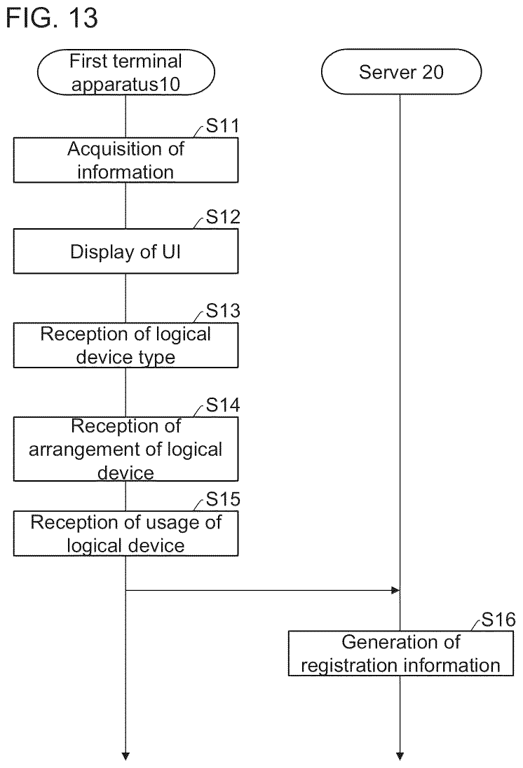

FIG. 13 is a flowchart showing an example of the operations of the first terminal apparatus 10 and the server 20 when generating registration information of logical devices.

First, the first user who operates the first terminal apparatus 10 operates the input device 13 to launch an application for setting logical devices on the architectural drawing data. Upon receiving a request from the first user, the control unit 190 of the first terminal apparatus 10 executes the requested application.

In step S11, the first terminal apparatus 10 acquires information necessary for setting the logical devices. Specifically, for example, in response to an operation by the first user, the transmission/reception unit 192 acquires architectural drawing data of the floor plan of a specific dwelling unit. The transmission/reception unit 192 may acquire the architectural drawing data from the server 20 or an external server. The presentation control unit 194 acquires information on logical device candidates to be arranged on the architectural drawing data from the device information 182 stored in the storage unit 180.

In step S12, the first terminal apparatus 10 presents to the first user a UI for arranging the logical devices on the architectural drawing data. Specifically, for example, the presentation control unit 194 causes the display 141 to display the architectural drawing data. The presentation control unit 194 causes an input interface for determining the type of the logical device to be displayed together with the architectural drawing data. For example, the presentation control unit 194 causes the display 141 to display a list of types of logical devices that can be arranged. The presentation control unit 194 may cause an input interface for determining a logical device to be displayed together with the architectural drawing data. For example, the presentation control unit 194 causes the display 141 to display a list of logical devices that can be arranged.

In addition, the presentation control unit 194 causes an input interface for determining the arrangement positions of the logical devices to be displayed together with the architectural drawing data. For example, the presentation control unit 194 causes the display 141 to selectively display the positions where the logical devices can be arranged. The presentation control unit 194 causes an input interface for setting the usages of the logical devices to be displayed together with the architectural drawing data. For example, the presentation control unit 194 causes the display 141 to display a list of usages that can be set.

In step S13, the first terminal apparatus 10 receives, from the first user, a designation of a type of the logical device to be arranged on the acquired architectural drawing data. Specifically, for example, the first user operates the input device 13, and designates a specific type from a list of types of logical devices (for example, bedroom light, light, sensor, controller, etc.) displayed on the display 141. The operation reception unit 191 receives a designation of a type input from the first user. It should be noted that what is received by the first terminal apparatus 10 from the first user is not limited to the designation of the type of the logical device, but may be a designation of a logical device.

In step S14, the first terminal apparatus 10 receives from the first user a designation of the arrangement of the logical device for which the type has been designated. Specifically, for example, the first user operates the input device 13 to select a specific position on the architectural drawing data. The operation reception unit 191 receives a designation of the arrangement position of the logical device input from the first user.

In step S15, the first terminal apparatus 10 receives from the first user a usage of the logical device for which the type and the position have been designated. Specifically, for example, the first user operates the input device 13 and designates a specific usage from the list of usages displayed on the display 141. The usages include, for example, a usage corresponding to the designated type. The operation reception unit 191 receives a designation of a usage input from the first user.

The first terminal apparatus 10 executes the processes of steps S13 to S15 for all the physical devices to be installed, arranges the corresponding logical devices on the architectural drawing data, and sets the usages of the logical devices. As a result, the type, arrangement position, and usage of each logical device corresponding to the physical device to be installed are stored in association with the architectural drawing data.

The first terminal apparatus 10 transmits, to the server 20, the architectural drawing data with which the types, arrangement positions, and usages of the logical devices are associated. The first terminal apparatus 10 may associate information on the building with the architectural drawing data. It should be noted that, when the first terminal apparatus 10 uses the API to associate the types, arrangement positions, usages, and the like of the logical devices without downloading the architectural drawing data, the first terminal apparatus 10 does not have to transmit the architectural drawing data to the server 20. At this time, the first terminal apparatus 10 transmits, to the server 20, for example, information on the types, arrangement positions, usages, and the like of the logical devices associated with the architectural drawing data.

In step S16, the server 20 receives the information transmitted from the first terminal apparatus 10. Specifically, the reception control module 2031 receives the architectural drawing data with which the types, the arrangement positions, and the usages of the logical devices are associated. The generation module 2033 stores the received architectural drawing data in a new record of the floor plan table 2021. The architectural drawing data with which the types, the arrangement positions, and the usages of the logical devices are associated is handled as so-called master data in the subsequent processing.

The generation module 2033 converts the architectural data and generates the type of each logical devices, the position coordinate at which the logical device is arranged, the information on the building, and the usage set for the logical device as registration information. The generation module 2033 determines, for example, the name of each logical device based on the type of the logical device. The physical device to be installed is set in advance, for example. Based on the set type, the generation module 2033 determines a name associated with the set type. In the registered information, for example, identification information of a logical device, a type of the logical device, information on the building, the position information, the usage, and the like are associated. The generation module 2033 stores the newly generated registration information in a new record of the logical device table 2022. The generation module 2033 stores a floor plan ID corresponding to the architectural drawing data received from the first terminal apparatus 10 in the item of floor plan ID of the record.

Further, the generation module 2033 calculates configuration information indicating how to operate the physical device based on the registered information. In addition, the generation module 2033 generates a floor plan image based on the architectural drawing data on which the logical devices are arranged.

### (Pairing Processing)

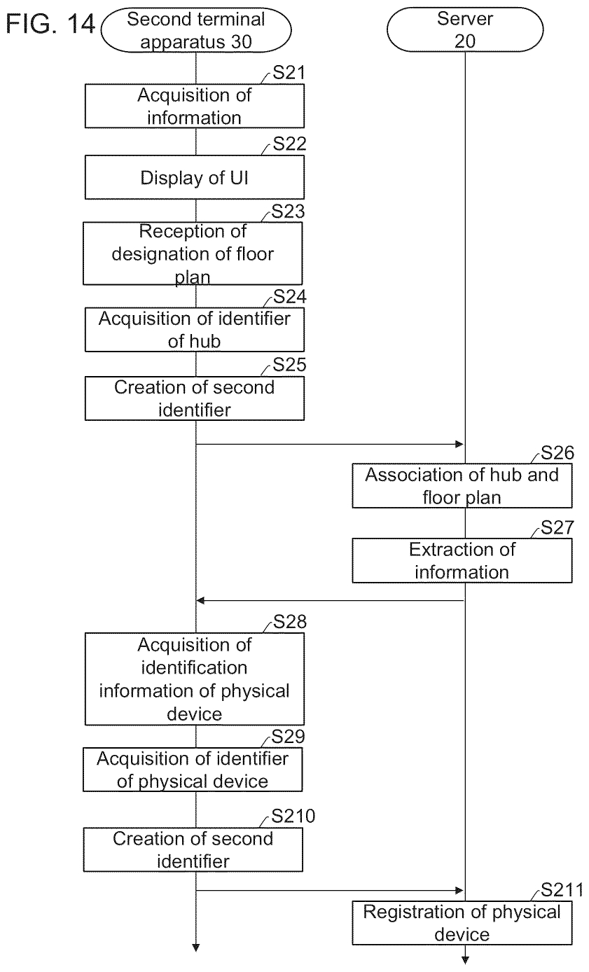

FIG. 14 is a flowchart showing an example of the operation of the server 20 and the second terminal apparatus 30 when pairing physical devices and a hub.

First, the second user who operates the second terminal apparatus 30 operates the input device 33 to launch an application for pairing a hub and physical devices. Upon receiving a request from the second user, the control unit 390 of the second terminal apparatus 30 executes the requested application.

In step S21, the second terminal apparatus 30 acquires information necessary for pairing between a hub and physical devices. Specifically, for example, in response to an operation by the second user, the transmission/reception unit 392 requests the server 20 for a list of floor plans. The control unit 203 of the server 20 transmits the information stored in each record of the floor plan table 2021 to the second terminal apparatus 30 in response to the request from the second terminal apparatus 30. The transmission/reception unit 392 receives the list of floor plans transmitted from the server 20.

In step S22, the second terminal apparatus 30 presents a UI for pairing a hub and physical devices to the second user. Specifically, for example, the presentation control unit 394 causes the display 341 to display the list of floor plans.

In step S23, the second terminal apparatus 30 receives a designation of a floor plan from the second user. Specifically, the second user operates the input device 33, and designates one floor plan from the list of floor plans displayed on the display 341. The operation reception unit 391 receives the designation of a floor plan input from the second user.

In step S24, the second terminal apparatus 30 receives an input of an identifier of the hub. Specifically, for example, the second user may input the identifier of the hub to the second terminal apparatus 30 by communicating with the hub through the communication unit 320. The identifier of the hub is, for example, a MAC address of the hub.

In step S25, the second terminal apparatus 30 generates a second identifier conforming to a predetermined standard based on the identifier of the hub. The second identifiers are identifiers for physical devices for operating services under the same standard. Specifically, for example, the control unit 390 generates a second identifier based on the type of the physical device and the MAC address, and the like. As described above, standardizing the identifier format facilitates the work of associating physical devices with logical devices to be described later. The control unit 390 transmits the floor plan ID of the floor plan designated by the second user and the second identifier of the hub to the server 20.

The control unit 390 generates a two-dimensional code by encoding the generated second identifier. The control unit 390 transmits information for printing the two-dimensional code to the printer. The printer prints a label on which the two-dimensional code is shown, in accordance with the information received from the second terminal apparatus 30. The second user attaches the printed label to the physical device whose identifier has been read. At this time, it is preferable that the label is attached at a position where the two-dimensional code can be visually recognized when the physical device is actually installed.

A label on which a two-dimensional code representing the second identifier is shown may be attached to the physical device in advance. For example, some physical devices are already compliant with the standard when they are shipped. In such a case, the control unit 390 causes the reader 333 to read the two-dimensional code shown on the label, but does not need to generate the second identifier and does not need to cause the printer to print the label either. On the other hand, a label on which a two-dimensional code of a different standard is shown may be attached to the physical device in advance. In this case, the control unit 390 reads the identifier of the physical device by communicating with the physical device through the communication unit 320, and generates the second identifier based on the read identifier. The control unit 390 causes the printer to print a label on which a two-dimensional code obtained by encoding the generated second identifier is shown. The second user attaches the printed label in place of the existing label. It should be noted that the second user may attach the printed label on the existing label.

In step S26, the server 20 associates the hub with the floor plan. Specifically, for example, the pairing module 2034 stores the floor plan ID and the second identifier received from the second terminal apparatus 30 in association with each other in a new record of the hub management table 2024. It should be noted that the second identifier may be generated by the server 20.

In step S27, the pairing module 2034 extracts information on the logical devices arranged in the floor plan associated with the hub. Specifically, for example, the pairing module 2034 searches the logical device table 2022 based on the floor plan ID associated with the hub, and acquires information of the item “name”. The transmission control module 2032 transmits a list of the names of the extracted logical devices, that is, a list of the names of the physical devices to be paired with the hub, to the second terminal apparatus 30.

In step S28, the second terminal apparatus 30 receives the list of the names of the physical devices from the server 20, and stores the list in the storage unit 380. The second terminal apparatus 30 may present the list of the names of the physical devices received from the server 20 to the user via the display 341.

In step S29, the second terminal apparatus 30 receives an input of a hub and the identifier of each physical device to be installed in the building. Specifically, for example, when the arrangement of the logical devices on the architectural drawing data is completed, the physical devices to be actually installed are ordered based on the arranged logical devices. The ordered physical devices are delivered to the second user. For example, the second user may input the identifier of each physical device to the second terminal apparatus 30 by communicating with the physical device through the communication unit 320. The identifier of the physical device is, for example, the MAC address of the hub.

In step S210, the second terminal apparatus 30 generates a second identifier conforming to a predetermined standard based on the identifier of the physical device. The control unit 390 transmits the second identifier of the physical device to the server 20.

The control unit 390 generates a two-dimensional code by encoding the generated second identifier. The control unit 390 transmits information for printing the two-dimensional code to the printer. The printer prints a label on which the two-dimensional code is shown, in accordance with the information received from the second terminal apparatus 30. The second user attaches the printed label to the physical device whose identifier has been read. At this time, it is preferable that the label is attached at a position where the two-dimensional code can be visually recognized when the physical device is actually installed.

In step S210, the second terminal apparatus 30 may determine whether or not the physical device whose identifier has been input is a physical device to be paired with the hub. Specifically, for example, the control unit 390 acquires the name of the physical device along with the identifier. The control unit 390 compares the acquired name with a list of names provided from the server 20, and determines whether or not the physical device whose identifier has been read is included in the list. When the name is included, the control unit 390 advances the pairing processing to the next processing. If not, the control unit 390 notifies the second user that the physical device is not a pairing target, and the pairing processing is not advanced to the next processing.

In step S211, the server 20 registers the physical device. Specifically, for example, the pairing module 2034 stores the physical device in a new record of the physical device table 2023 in association with the second identifier and the floor plan ID. The pairing module 2034 may store the second identifier of the hub to be paired in association with the newly registered physical device.

When the hub and the physical device are registered, the second user pairs the hub with the physical device. Specifically, for example, the second user presses a predetermined button to transition the hub and the physical device to a pairing mode. The second user brings the hub and the physical device that have entered the pairing mode close to each other. Accordingly, pairing requests are automatically exchanged between the hub and the physical device by the Zigbee (registered trademark) protocol, and information necessary for the hub and the physical device to detect each other and communicate with each other is exchanged. The hub stores the received information in the storage unit, thereby performing pairing setting between the physical device and the hub. The hub transmits to the second terminal apparatus 30 information indicating that pairing with the physical device has been completed. The second terminal apparatus 30 causes the display 341 to display that pairing between the physical device and the hub has been completed.

The second user repeats the code reading operation of the hub in step S24 and the code reading operation of the physical device in step S29 until the pairing of all the physical devices included in the list acquired by the second terminal apparatus 30 in step S28 is completed. The second terminal apparatus 30 and the server 20 repeat the operations from step S23 to step S211 in response to the operation of the second terminal apparatus 30 by the second user.

After the pairing of the physical devices to be paired with the hub is completed, the paired hub and physical devices are packaged and delivered to the construction site. That is, in the present embodiment, since the pairing between the hub and the physical devices is completed at the shipment stage before the installation in the building, it is not necessary to perform the pairing between the physical devices and the hub at the construction site. Therefore, it is possible to reduce the time and effort of work at the construction site.

Further, as described above, in the pairing processing, the physical devices and the hub are paired for each floor plan. Therefore, when a building includes a plurality of dwelling units having a common floor plan, the hubs and the physical devices can be delivered to the site without distinguishing the dwelling units having the common floor plan from each other. Therefore, it is possible to reduce the time and effort in delivering the physical devices. In addition, it is possible to reduce the time and effort of work at the construction site.

After the delivery of the physical devices is completed, the worker who is responsible for installing the physical devices installs the hubs and the physical devices at the installation positions in accordance with the floor plan and the electrical wiring plan. At this time, the worker can install the hubs and the physical devices without distinguishing the dwelling units having the common floor plan from each other as in the delivery. Therefore, it is possible to reduce the time and effort of work at the construction site.

### (Association Processing)

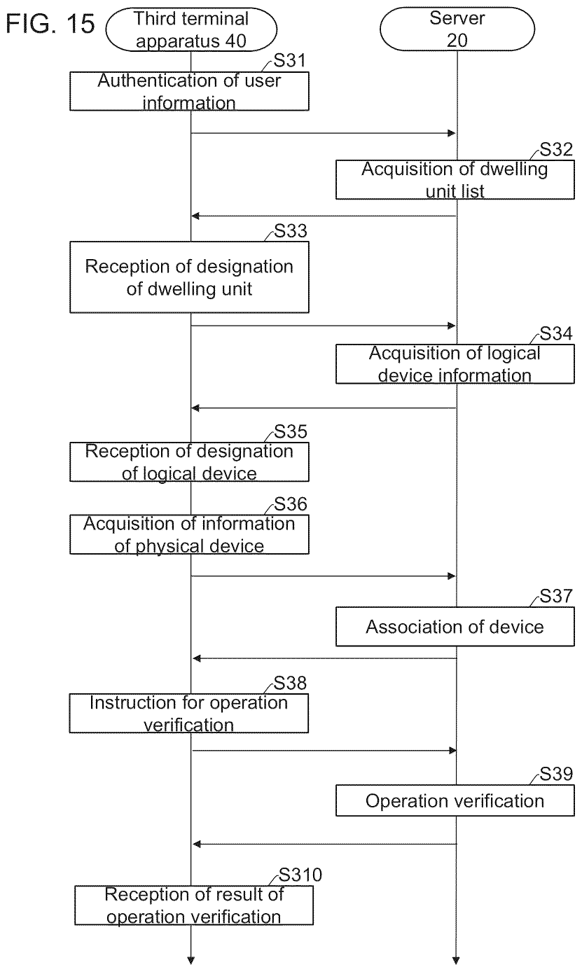

FIG. 15 is a flowchart showing an example of the operations of the third terminal apparatus 40 and the server 20 when associating physical devices actually installed in a dwelling unit with logical devices arranged on dwelling unit drawing data. The association processing described with reference to FIG. 15 is performed after the worker installs the physical devices in the building.

The control unit 203 of the server 20 stores the information on each dwelling unit provided in the building in the storage unit 202 at an arbitrary timing before executing the association processing. Specifically, for example, the control unit 203 stores, for each dwelling unit provided in the building, the building ID, the dwelling unit number, and the floor plan ID corresponding to the dwelling unit in a new record of the dwelling unit table 2025. The information stored in the dwelling unit table may be transmitted to the server 20 by a specific user operating a specific terminal apparatus. In addition, the control unit 203 stores information on logical devices that require association in the storage unit 202 at an arbitrary timing before executing the association processing. Specifically, for example, the control unit 203 stores the association ID, the dwelling unit ID, the logical device ID, and the status in a new record of the association table 2026 for each logical device that requires association.

In step S31, the third terminal apparatus 40 authenticates a third user, a staff member who associates logical devices with physical devices. Specifically, the third user causes the third terminal apparatus 40 to execute an application for performing association. When the third terminal apparatus 40 executes the application, the control unit 490 causes the display 441 to display a login screen for authenticating the user.

The third user inputs, for example, a user ID and a password on the login screen. The information input by the third user on the login screen is not limited to the user ID and the password. Upon completion of the user authentication, the control unit 490 connects to the server 20 in association with the user ID.

In step S32, the control unit 203 acquires information of a dwelling unit stored in the storage unit 202. Specifically, for example, the control unit 203 acquires information stored in each record of the dwelling unit table. The control unit 203 transmits the acquired information to the third terminal apparatus 40.

In step S33, the control unit 490 receives the information transmitted from the server 20. The control unit 490 causes the display 441 to display a list of building names received from the server 20. The third user designates a building to be an association target from the list of buildings displayed on the display 441. Upon receiving the designation of the building, the control unit 490 causes the display 441 to display the information on the dwelling units included in the building.

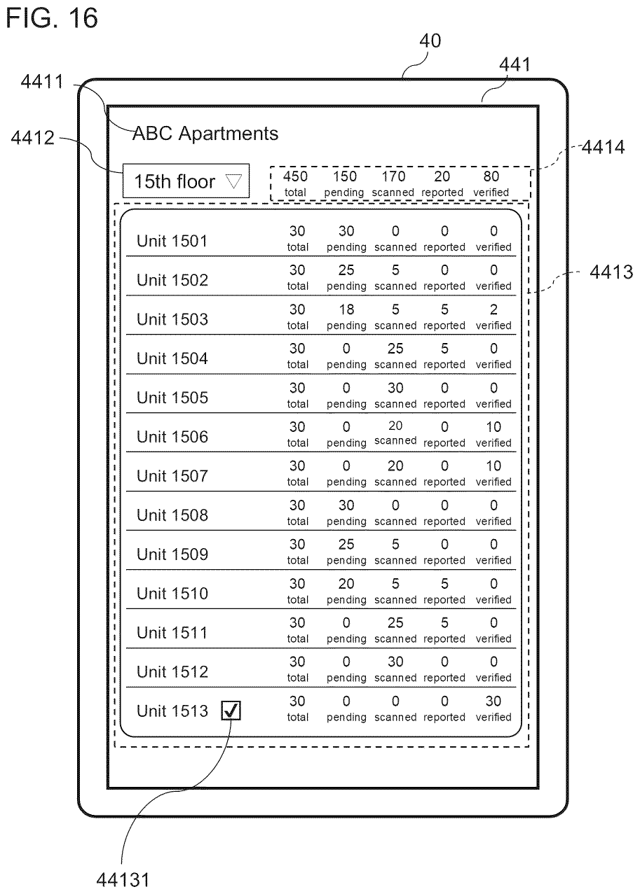

FIG. 16 is a schematic diagram showing an example of information on dwelling units included in a building designated by the third user, which is displayed on the third terminal apparatus 40. On the screen shown in FIG. 16, a list of dwelling units on the 15th floor of an apartment complex named “ABC Apartments” is displayed. On the screen shown in FIG. 16, an object 4411 indicating the name of the building is displayed.

On the screen shown in FIG. 16, an object 4412 indicating the floor on which the dwelling units displayed on the current screen are located is displayed. When the user presses the object 4412, a screen for designating another floor of the building displayed in the object 4411 is displayed. The user can change the floor for which information on the dwelling units is to be displayed by designating a specific floor on the displayed screen.

On the screen shown in FIG. 16, an area 4413 indicating the progress status of the association in each dwelling unit located on the floor shown in object 4412 is displayed. In FIG. 16, the area 4413 indicates that a total of 30 physical devices to be associated are installed in each dwelling unit. In FIG. 16, the area 4413 indicates that the number of physical devices in the not-yet-started state in Unit 1503 is 18. In FIG. 16, the area 4413 indicates that the number of physical devices in the scanned state in Unit 1503 is five. In FIG. 16, the area 4413 indicates that the number of physical devices in the reported state in Unit 1503 is five. In FIG. 16, the area 4413 indicates that the number of physical devices in the verified state in Unit 1503 is two.

In FIG. 16, regarding a dwelling unit for which the association and operation verification of all the physical devices are completed, the area 4413 shows an object 44131 indicating that the association and operation verification of all the physical devices in the dwelling unit are completed.

On the screen shown in FIG. 16, an area 4414 indicating the progress state of the association of the physical devices of all dwelling units located on the floor shown in the object 4412 is displayed. On the screen shown in FIG. 16, the area 4414 shows a total of the physical devices installed in the dwelling units on the 15th floor, a total of the physical devices in the not-yet-started state, a total of the physical devices in the scanned state, a total of the physical devices in the reported state, and a total of the physical devices in the verified state.

The third terminal apparatus 40 receives a designation of a dwelling unit for which the association is to be performed by the third user. Specifically, for example, the third user presses an item indicating the dwelling unit for which the association is to be performed among the dwelling units included in the area 4413 shown in FIG. 16. The third terminal apparatus 40 transmits the dwelling unit ID and the floor plan ID of the designated dwelling unit, and the user ID of the third user to the server 20.

In step S34, the control unit 203 acquires the information on the floor plan associated with the dwelling unit designated by the third user and information on the logical devices from the storage unit 202. Specifically, for example, the control unit 203 searches the floor plan table 2021 and the logical device table 2022 based on the floor plan ID received from the third terminal apparatus 40, and acquires information of the corresponding record.

Based on the information acquired from the storage unit 202, the control unit 203 transmits, to the third terminal apparatus 40, information for causing the third terminal apparatus 40 to display the floor plan of the dwelling unit, which indicates the arrangement positions of the logical devices.

Further, the control unit 203 searches the association table 2026 using the dwelling unit ID received from the third terminal apparatus 40, and stores the user ID of the third user in the item “user in charge” of the corresponding record. This makes it possible to inform other third users that the third user is in charge of the association processing of the dwelling unit.

In step S35, the third terminal apparatus 40 causes the display 441 to display the floor plan of the dwelling unit designated by the third user and the list of logical devices associated with the floor plan.

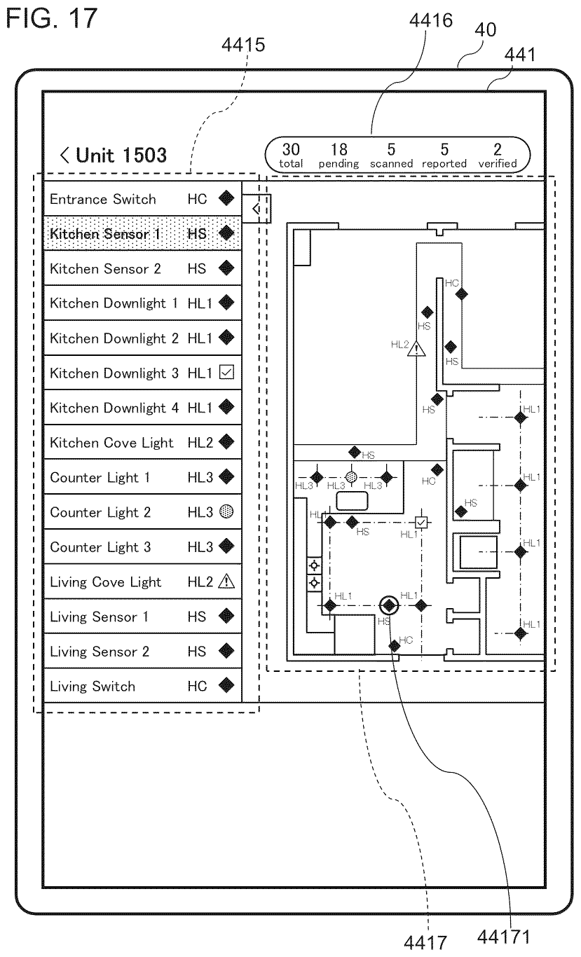

FIG. 17 is a schematic diagram showing an example of a screen displaying a floor plan and a list of logical devices, which is displayed on the third terminal apparatus 40. The screen shown in FIG. 17 includes an area 4417 showing an image of the floor plan of the dwelling unit designated by the third user. In the image of the floor plan, an icon indicating that a physical device needs to be installed is shown at a position corresponding to the position coordinates stored in the item “position information” of the logical device table 2022. The appearance of the icon may be changed in accordance with the progress status of the association of the physical device. For example, on the screen shown in FIG. 17, icons are displayed in different colors and shapes for the not-yet-started state, the scanned state, the reported state, and the verified state.

The screen shown in FIG. 17 includes an area 4415 showing a list of logical devices arranged on the drawing data designated by the third user. In FIG. 17, the area 4415 shows a list of logical devices arranged on the floor plan image shown in the area 4417. In the list of logical devices shown in the area 4415, the item of each logical device shows the same icon as the icon indicating the position of the logical device shown on the floor plan image in the area 4417. In the list of logical devices shown in the area 4415, the items of the logical devices are displayed in different colors in accordance with the progress statuses of the association of the logical devices.

The screen shown in FIG. 17 includes an area 4416 showing the number of logical devices for each association progress state in the dwelling unit designated by the third user. In FIG. 17, the area 4416 indicates that the number of physical devices to be associated is 30 in total, the number of physical devices in the not-yet-started state is 18, the number of physical devices in the scanned state is five, the number of physical devices in the reported state is five, and the number of physical devices in the verified state is two.

The third terminal apparatus 40 receives a designation of an arrangement position of a logical device from the third user. Specifically, for example, the third user presses an icon indicating the arrangement position of the logical device from the image of the floor plan included in the area 4417 shown in FIG. 17. When an arrangement position is designated, the third terminal apparatus 40 causes the display 441 to display an instruction to read information related to the association of the physical device installed at the arrangement position with the logical device. The third terminal apparatus 40 may cause the display 441 to display at least one of the type, the name, and the progress status of association of the logical device related to the designated position.

The third terminal apparatus 40 may receive a selection of a logical device to be associated from the list of logical devices, instead of receiving a designation of an arrangement position of a logical device. Specifically, for example, the third user may press an item of a logical device to be associated from the list of logical devices included in the area 4415 shown in FIG. 17. Upon receiving the selection of the logical device, the third terminal apparatus 40 causes the selected position of the logical device to be displayed on the floor plan so as to be identifiable from the other logical devices. Specifically, for example, the third terminal apparatus 40 causes an icon indicating the position of the logical device designated by the third user to be shown on the floor plan image shown in FIG. 17, in such a manner that it is enclosed by an icon 44171.

In step S36, the third terminal apparatus 40 receives an input of information for identifying the physical device. Specifically, for example, the third user inputs the second identifier of the physical device to the third terminal apparatus 40 by reading the code assigned to the physical device with the camera 460 of the third terminal apparatus 40. The third terminal apparatus 40 transmits the logical device ID of the logical device designated in step S35, the acquired second identifier, and the user ID of the third user to the server 20.

In step S37, the control unit 203 causes the association module 2035 to associate the installed physical device with the logical device arranged on the architectural drawing data based on the information read by the third terminal apparatus 40. Specifically, for example, the association module 2035 searches the association table 2026 based on the logical device ID received from the third terminal apparatus 40, and stores the second identifier received from the third terminal apparatus 40 in the item of physical device ID. As a result, the physical device installed in the building is bound to the logical device logically arranged at the position where the physical device is installed. The physical device operates according to the specification set for the logical device.

In addition, the control unit 203 causes the progress management module 2036 to change the item of progress status to the scanned state. This makes it possible to share the progress status of the association between the logical device and the physical device with users other than the third user.

The control unit 203 transmits, to the third terminal apparatus 40, information indicating that the physical device and the logical device have been associated with each other.

In step S38, the third terminal apparatus 40 causes the display 441 to display a screen for receiving an instruction for the operation verification of the associated physical device.

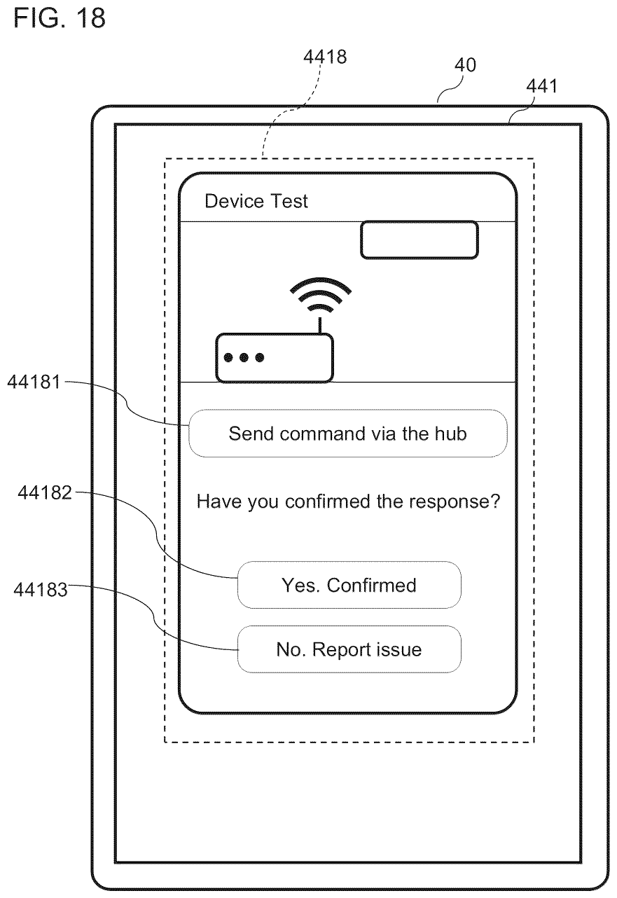

FIG. 18 is a schematic diagram showing an example of a screen, displayed by the third terminal apparatus 40, for receiving an instruction for the operation verification of the associated physical device. The screen shown in FIG. 18 is overlaid on the screen shown in FIG. 17, for example. The screen shown in FIG. 18 includes an area 4418 displaying a button for receiving an input of the third user related to the operation verification.

In FIG. 18, a button 44181 for transmitting a signal for driving the physical device is displayed in the area 4418. When the third user presses the button 44181, the third terminal apparatus 40 transmits an instruction for the operation verification to the server 20. The control unit 203 refers to the logical device table 2022 and the association module 2035 for example and, based on the position on the floor plan image, identifies a physical device associated with the logical device arranged at the position. The control unit 203 refers to the physical device table 2023 and acquires the hub ID of the hub paired with the identified physical device. The association module 2035 refers to the hub management table 2024 and identifies a hub paired with the associated physical device based on the acquired hub ID. The association module 2035 instructs the identified hub to perform the operation verification of the physical device.

When the hub receives the instruction from the server 20, the hub transmits a signal for performing a predetermined operation on the physical device to be verified. The physical device receives a signal from the hub and performs an operation according to the instruction.

In step S38, the third terminal apparatus 40 receives an input of a verification result of the operation of the associated physical device, and stores the received verification result in the storage unit 480. Specifically, for example, when the third user can confirm that the associated physical device has correctly operated, the third user presses a button 44182 displayed on the screen shown in FIG. 18. In this case, the third terminal apparatus 40 stores information indicating that the associated physical device has correctly operated in the storage unit 480. When the reaction of the associated physical device cannot be confirmed, the third user presses a button 44183 displayed on the screen shown in FIG. 18. In this case, the third terminal apparatus 40 stores, in the storage unit 480, information indicating that the associated physical device did not operate correctly.

The third terminal apparatus 40 transmits, to the server 20, information on the verification result of the operation of the physical device received from the third user.

In step S39, the control unit 203 receives a result of the operation verification of the physical device by the reception control module 2031. The control unit 203 updates the progress status of the association by the progress management module 2036. Specifically, for example, the progress management module 2036 searches the association table based on the physical device ID received from the third terminal apparatus 40, and updates the value of the item of the progress status. The control unit 203 transmits, to the third terminal apparatus 40, information indicating that the progress status of the association has been updated, by the transmission control module 2032.

In step S310, upon receiving the notification, the third terminal apparatus 40 changes the appearance of the icon representing the logical device, for which the association has been performed and which is included in the area 4415 and area 4416, on the screen shown in FIG. 17 in accordance with the progress status of the association. For example, when the physical device has operated correctly in the operation verification, the third terminal apparatus 40 changes the icon of the corresponding logical device to an appearance corresponding to the verified state. For example, when the physical device has not operated correctly in the operation verification, the third terminal apparatus 40 changes the icon of the corresponding logical device to an appearance corresponding to the reported state.

Thus, the association of the logical device designated in step S35 with a physical device is completed. When the association between the logical device and the physical device is completed, the third user selects a logical device that has not been associated with a physical device from the area 4415 shown in FIG. 17. The third terminal apparatus 40 and the server 20 repeat the processes from step S35 to step S310 until, for example, there are no logical devices that have not been associated in the area 4415.

As described above, in the embodiment, the control unit 203 receives an input of the arrangement of each logical device and an input of a usage thereof from the first terminal apparatus 10 on the architectural drawing data of the predetermined building. The control unit 203 registers the arrangement positions and operation settings of the logical device based on the architectural drawing data with which the arrangements and usages of the logical devices are associated. The control unit 203 receives, from the second terminal apparatus 30, identification information of the physical devices to be installed in the building and identification information of the hub to be installed in the building. A label capable of identifying identification information of each physical device is attached to the physical device, and a label capable of identifying identification information of the hub is attached to the hub. The control unit 203 registers the identification information of the physical device and the identification information of the hub, and pairs the physical device with the hub. After the physical devices and the hub are installed in the building, the control unit 203 causes the third terminal apparatus 40 to display a floor plan image of the building, which shows the arrangement positions of the logical devices. When an arrangement position is designated on the floor plan image via the third terminal apparatus 40, the control unit 203 causes the third terminal apparatus 40 to display a request for the physical device or the hub installed at the arrangement position. In response to the request, the control unit 203 associates the identification information read from the physical device or the hub by the third terminal apparatus 40 with the logical device to be arranged on the floor plan image.

To minimize the on-site work, it is desirable to complete all feasible processing steps as much as possible prior to installation. In the conventional technique, for example, physical device settings such as pairing of physical devices are performed on site, placing a significant burden on installers. In the present embodiment, on-site commissioning is minimized. That is, in the present embodiment, part of the commissioning (pairing, registration of the physical devices) is completed before shipment of the physical devices, and only the position information of the physical devices needs to be registered on-site. This enables the reduction of uncertainties and labor costs on-site.

Thus, according to the present disclosure, it is possible to reduce the costs and time and effort in the series of processes—from the design stage of a property into which smart home devices are introduced, through to construction, setting, and operational verification.

In addition, by determining the arrangements of the logical devices on the architectural drawing data and using the architectural drawing data as the master data, the design cannot be modified on-site. This prevents careless design changes and enables stable construction schedules. Furthermore, building information modeling and the like can be performed from a single source based on the master data, making the work more efficient.

In addition, in the above-described embodiment, the control unit 203 causes a list of logical devices that need to be associated with physical devices to be displayed, and upon receiving a selection of a logical device shown in the list, displays a corresponding position on the floor plan image so as to be distinguishable from the positions corresponding to the other logical devices. This enables the system to easily and reliably guide the staff member to the precise location where association with a physical device is required.

In addition, in the above-described embodiment, upon receiving a selection of a specific position on the floor plan image, the control unit 203 causes the name of the logical device corresponding to the selected position to be displayed. This enables the system to prevent the staff member from mistaking the physical device to be associated.

In addition, in the above-described embodiment, upon receiving an instruction to verify the operation of an installed physical device, the control unit 203 transmits a signal for driving the physical device to the position at which the physical device is installed. This makes it possible to associate the physical device with the installation position and to verify the operation of the physical device at the same time. Therefore, it is possible to proceed with the work more efficiently.

In addition, in the above-described embodiment, the control unit 203 receives an input of whether or not the installed physical device has been driven, and stores the result. This makes it possible to accurately store the verification result for each physical device.

In addition, in the above-described embodiment, the control unit 203 manages unassociated logical devices, associated logical devices, logical devices that are associated but have failed in the verification, or logical devices that have been verified. This allows the physical devices to be installed in the building as intended at the design stage.

In addition, in the above-described embodiment, the control unit 203 causes the number of unassociated logical devices, the number of associated logical devices, the number of logical devices that are associated but have failed in the verification, or the number of logical devices that have been verified to be displayed. This makes it possible to accurately grasp the construction schedule.

### Modifications

In the above-described embodiment, the system 1 performs the processes described in the above embodiment on buildings equipped with dwelling units for human habitation. However, the buildings on which the processes by the system 1 are performed are not particularly limited. The system 1 can also perform the processes on, for example, buildings where people work, buildings where people stay for some purpose, and buildings for storing specific items.

In the above-described embodiment, the first terminal apparatus 10 receives, from the user, a designation of an arrangement of a logical device on the drawing data of the floor plan. However, the first terminal apparatus 10 may use the presentation control unit 194 to propose an arrangement of a logical device based on the floor plan of the building, for example. Specifically, for example, upon acquiring architectural drawing data, the presentation control unit 194 acquires information on the feature of the room included in the architectural drawing data. The information on the feature of the room is, for example, information on the layout of the room, the dimensions of the room, the shape of the room, the arrangement of furniture, or a combination of at least any of these. The presentation control unit 194 receives a designation of a logical device from the user. The presentation control unit 194 proposes an arrangement of the designated logical device based on the acquired information on the feature of the room. The presentation control unit 194 may propose the arrangement of the designated logical device based on a predetermined table or using a trained model. The trained model is trained by, for example, supervised learning or reinforcement learning so as to output, when a logical device and architectural drawing data are input, an arrangement of the selected logical device, based on the relationship between the feature of the room and the physical devices installed in the room. The presentation control unit 194 inputs, for example, architectural drawing data and a logical device designated by the user to the trained model to cause the trained model to output an arrangement suitable for the logical device. The user may accept the presented proposal or may not adopt the proposal. In addition, the user may modify and adopt the presented proposal.

In the above-described embodiment, the first terminal apparatus 10 receives a designation of a logical device from the first user. However, the first terminal apparatus 10 may use the presentation control unit 194 to propose logical devices that can be arranged on the floor plan based on the architectural drawing data, for example. Specifically, for example, upon acquiring architectural drawing data, the presentation control unit 194 acquires information on the feature of the room included in the architectural drawing data. Based on the acquired information, the presentation control unit 194 identifies logical device candidates to be arranged in the room and arrangement position candidates, and proposes them to the first user. The presentation control unit 194 may propose the logical device candidates and the placement position candidates based on a predetermined table or using a trained model. The trained model is trained by, for example, supervised learning or reinforcement learning so as to output logical device candidates when architectural drawing data is input, based on the relationship between the feature of the room and the physical devices installed in the room. The user may accept the presented proposal or may not adopt the proposal. In addition, the user may modify and adopt the presented proposal.

Further, the first terminal apparatus 10 may propose logical devices that can be arranged at a position designated by the user on the architectural drawing data. Specifically, for example, the presentation control unit 194 receives, from the user, a designation of a position at which a logical device is to be arranged on the architectural drawing data. The presentation control unit 194 identifies logical device candidates to be installed at the designated position from the information on the feature of the room and the designated position, and proposes the logical device candidates to the user. The presentation control unit 194 may propose the logical devices to be installed at the designated position based on a predetermined table or using a trained model. The trained model is trained by, for example, supervised learning or reinforcement learning so as to output logical device candidates when architectural drawing data and a position on the architectural drawing data are input, based on the relationship between the feature of the room and the physical devices installed in the room. The user may accept the presented proposal or may not adopt the proposal. In addition, the user may modify and adopt the presented proposal.

Further, the first terminal apparatus 10 may use the presentation control unit 194 to propose the usage of the logical device based on the logical device designated by the user and the arrangement position of the logical device. Specifically, for example, when a designation of a logical device and a designation of a position at which the logical device is to be arranged are received from the user, the presentation control unit 194 proposes a usage of the designated logical device at the designated position based on the architectural drawing data. The presentation control unit 194 may propose the usage of the logical device based on a predetermined table or using a trained model. The trained model is trained by, for example, supervised learning or reinforcement learning so as to output the usage of the logical device when the logical device, the arrangement position, and the architectural drawing data are input, based on the relationship among the feature of the room, the physical devices installed in the room, and the usages of the installed physical devices. The user may accept the presented proposal or may not adopt the proposal. In addition, the user may modify and adopt the presented proposal.

Further, the first terminal apparatus 10 may use, for example, the presentation control unit 194 to propose the arrangement position and the usage of the logical device based on the designation of the logical device by the user. The first terminal apparatus 10 may also use, for example, the presentation control unit 194 to propose a logical device and a usage based on the designation of a position on the architectural drawing data, for example. The user may accept the presented proposal or may not adopt the proposal. In addition, the user may modify and adopt the presented proposal.

In addition, in the above-described embodiment, the system 1 executes the processing related to the pairing and the processing related to the association based on the registration information. In addition, the system 1 may generate order information for ordering necessary physical devices based on the registration information. Specifically, for example, the control unit 203 of the server 20 searches the logical device table 2022 based on a specific floor plan ID, and acquires information of the item “name”. As a result, the control unit 203 acquires a list of physical devices necessary for the dwelling units built based on the floor plan. The control unit 203 generates order information including the names and quantities of the physical devices based on the acquired list of physical devices. This makes it possible to reduce the labor of generating the order information. Additionally, since ordering of parts and the like can be performed from a single source based on the master data, the work becomes more efficient.

Further, in the above embodiment, the third terminal apparatus 40 does not particularly limit the display destination of the information of the logical devices. However, the third terminal apparatus 40 may not display the information on the logical devices to other staff members than a predetermined staff member. Specifically, when the process for associating a specific logical device is being performed, the information for associating the logical device may not be displayed to other staff members than the staff member in charge of associating the logical device. For example, when an item related to a logical device is selected on the screen shown in FIG. 17 on the terminal apparatus of a staff member not in charge while the processing related to association of the logical device is being executed on a terminal apparatus of a staff member in charge, a message indicating that the operation related to the association of the logical device has been locked by another staff member may be displayed instead of displaying information for associating the logical device.

The third terminal apparatus 40 may be configured such that, when another third user accesses the screen shown in FIG. 17 for a specific dwelling unit, a third user who operates the third terminal apparatus 40 cannot access the screen shown in FIG. 17 for the dwelling unit. For example, when a third user who operates the third terminal apparatus 40 requests processing for a specific dwelling unit, the third terminal apparatus 40 determines whether or not another third user is performing the association processing for the dwelling unit. For example, the third terminal apparatus 40 accesses the server 20 and identifies whether or not another third user is stored as the user in charge in the record of the dwelling unit in the association table 2026. The third terminal apparatus 40 may be configured, when another third user is performing the association processing for the specific dwelling unit, not to access the screen shown in FIG. 17 for the specific dwelling unit until another third user finishes the association processing. In other words, when the association between a physical device and a logical device is being executed via a specific third terminal apparatus 40 among a plurality of third terminal apparatuses 40, the control unit 203 does not allow execution of processing via another third terminal apparatus 40. As a result, it is possible to restrict the display of the information on the logical devices associated with the dwelling unit to other staff members. In addition, it is possible to avoid the site from being crowded with a plurality of persons in charge.

### <4 Basic Hardware Configuration of Computer>

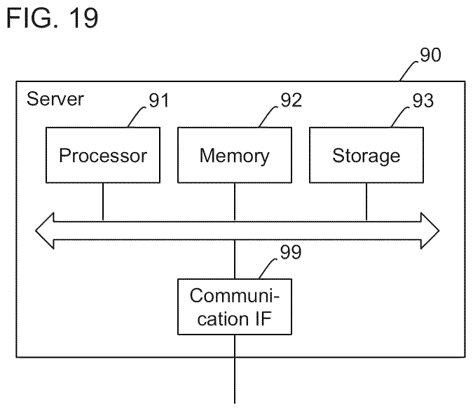

FIG. 19 is a block diagram showing a basic hardware configuration of the computer 90. The computer 90 includes at least a processor 91, a main storage device 92, an auxiliary storage device 93, and a communication interface (IF) 99. These are electrically connected to each other by a bus.

The processor 91 is hardware for executing an instruction set described in a program. The processor 91 is composed of an arithmetic unit, a register, a peripheral circuit, and the like.

The main storage device 92 is used to temporarily store a program, data to be processed by the program, etc., and the like. For example, it is a volatile memory such as a dynamic random access memory (DRAM).

The auxiliary storage device 93 is a storage device for storing data and programs. For example, it is a flash memory, a hard disc drive (HDD), a magneto-optical disk, a CD-ROM, a DVD-ROM, a semiconductor memory, or the like.

The communication IF 99 is an interface for inputting and outputting signals to communicate with other computers through a network using a wired or wireless communication standard.

The network is composed of various mobile communication systems, etc. constructed by the Internet, a LAN, a wireless base station, etc. For example, the network includes a 3G, 4G, or 5G mobile communication system, long term evolution (LTE), a wireless network (such as Wi-Fi (registered trademark)) connectable to the Internet by a given access point, and the like. In the case of wireless connection, examples of the communication protocol include Z-Wave (registered trademark), ZigBee (registered trademark), and Bluetooth (registered trademark). In the case of wired connection, the network includes ones with direct connection by a universal serial bus (USB) cable or the like.

It should be noted that the computer 90 can be virtually realized by distributing all or part of each hardware configuration to a plurality of computers 90 and interconnecting them via a network. As described above, the computer 90 is a concept that includes not only the computer 90 housed in a single housing or case but also a virtualized computer system.

### <Basic Functional Configuration of Computer 90>

A functional configuration of the computer realized by the basic hardware configuration of the computer 90 shown in FIG. 19 will be described. The computer includes at least functional units of a control unit, a storage unit, and a communication unit.

The functional units of the computer 90 may be realized by distributing all or part of the functional units to a plurality of computers 90 connected to each other through a network. The computer 90 is a concept that includes not only a single computer 90 but also a virtualized computer system.

The control unit is realized by the processor 91 reading out various programs stored in the auxiliary storage device 93, loading them into the main storage device 92, and executing processes in accordance with the programs. The control unit can realize functional units that perform various types of information processing depending on the type of program. Thus, the computer is realized as an information processing apparatus that performs information processing.

The storage unit is realized by the main storage device 92 and the auxiliary storage device 93. The storage unit stores data, various programs, and various databases. In addition, the processor 91 can reserve a storage area corresponding to the storage unit in the main storage device 92 or the auxiliary storage device 93 in accordance with a program. In addition, the control unit can cause the processor 91 to execute processing for adding, updating, and deleting data stored in the storage unit in accordance with various programs.

The database refers to a relational database for managing a set of data, called a tabular table, structurally defined by rows and columns, in relation to each other. In the database, a table is called a table, a table column is called a column, and a table row is called a record. In the relational database, relationships between tables can be set so that the tables are associated with each other.

Normally, a column as a key for uniquely identifying a record is set in each table, but it is not necessary to set a key for a column. The control unit can cause the processor 91 to execute addition, deletion, and update of a record in a specific table stored in the storage unit in accordance with various programs.

The communication unit is realized by the communication IF 99. The communication unit realizes the function of communicating with another computer 90 through a network. The communication unit can receive information transmitted from another computer 90 and input the information to the control unit. The control unit can cause the processor 91 to execute information processing on the received information in accordance with various programs. Further, the communication unit can transmit information output from the control unit to another computer 90.

Although some embodiments of the present disclosure have been described above, these embodiments can be implemented in various other forms, and various omissions, replacements, and changes can be made without departing from the spirit of the invention. These embodiments and their modifications are included in the scope and spirit of the invention and are included in the scope of the claimed inventions and their equivalents. The functionality of the elements disclosed herein may be implemented using circuitry or processing circuitry which includes general purpose processors, special purpose processors, integrated circuits, ASICs (“Application Specific Integrated Circuits”), conventional circuitry and/or combinations thereof which are configured or programmed to perform the disclosed functionality. Processors are considered processing circuitry or circuitry as they include transistors and other circuitry therein. In the disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

### APPENDIXES

The matters described in the above embodiments will be appended below.

### Appendix 1

A system comprising one or more information processing apparatuses, wherein
the one or more information processing apparatuses include processing circuitry, and
the processing circuitry is configured to:
   receive, from a first terminal, an input of an arrangement of a logical device and an input of a usage of the logical device on architectural drawing data of a specific building;
   register an arrangement position and operation setting of the logical device based on the architectural drawing data with which the arrangement and usage of the logical device are associated;
   receive, from a second terminal, identification information of a physical device to be installed in the building and identification information of a hub to be installed in the building, a label that allows identification of the identification information of the physical device being attached to the physical device, and a label that allows identification of the identification information of the hub being attached to the hub;
   register the identification information of the physical device and the identification information of the hub, and pair the physical device with the hub;
   after the physical device and the hub are installed in the building, cause a third terminal to display a floor plan image of the building showing the arrangement position of the logical device;
   when the arrangement position is designated on the floor plan image via the third terminal, cause the third terminal to display a request for a physical device or a hub installed at the arrangement position; and
   in response to the request, associate the identification information read from the physical device or the hub by the third terminal with the logical device arranged on the floor plan image.

### Appendix 2

The system according to Appendix 1, wherein the processing circuitry proposes an arrangement of the logical device based on a layout of the building.

### Appendix 3

The system according to Appendix 1 or 2, wherein the processing circuitry proposes a logical device that can be arranged, based on a layout of the building.

### Appendix 4

The system according to any one of Appendixes 1 to 3, wherein the processing circuitry proposes a logical device that can be arranged at a designated position on the architectural drawing data.

### Appendix 5

The system according to any one of Appendixes 1 to 4, wherein the processing circuitry generates order information for ordering a required physical device, based on the architectural drawing data with which the arrangement and usage of the logical device are associated.

### Appendix 6

The system according to any one of Appendixes 1 to 5, wherein
the processing circuitry
displays a list of a logical device required to be associated with a physical device, and
when a selection of a logical device from the logical device displayed in the list is received, displays a corresponding position on the floor plan image so as to be distinguishable from a position corresponding to another logical device.

### Appendix 7

The system according to any one of Appendixes 1 to 6, wherein
upon receiving a selection of a specific position on the floor plan image, the processing circuitry causes the selected position and a name of a corresponding logical device to be displayed.

### Appendix 8

The system according to any one of Appendixes 1 to 7, wherein
when association between the physical device and the logical device is being executed via a specific third terminal among a plurality of the third terminals, the processing circuitry refrains from allowing execution of processing via another third terminal.

### Appendix 9

The system according to any one of Appendixes 1 to 8, wherein
upon receiving an instruction to verify an operation of an installed physical device, the processing circuitry transmits a signal for driving the physical device to a position at which the physical device is installed.

### Appendix 10

The system according to Appendix 9, wherein
the processing circuitry receives an input of whether or not the installed physical device has been driven, and stores a result.

### Appendix 11

The system according to Appendix 10, wherein
the processing circuitry manages an unassociated logical device, an associated logical device, a logical device that is associated but has failed in verification, or a logical device that has been verified.

### Appendix 12

The system according to Appendix 11, wherein
the processing circuitry causes a number of the unassociated logical device, a number of the associated logical device, a number of the logical device that is associated but has failed in the verification, or a number of the logical device that has been verified to be displayed.

### Appendix 13

A method executed by processing circuitry included in one or more information processing apparatuses in a system including the one or more information processing apparatuses, wherein
the processing circuitry
   receives, from a first terminal, an input of an arrangement of a logical device and an input of a usage of the logical device on architectural drawing data of a specific building;
   registers an arrangement position and operation setting of the logical device based on the architectural drawing data with which the arrangement and usage of the logical device are associated;
   receives, from a second terminal, identification information of a physical device to be installed in the building and identification information of a hub to be installed in the building, a label that allows identification of the identification information of the physical device being attached to the physical device, and a label that allows identification of the identification information of the hub being attached to the hub;
   registers the identification information of the physical device and the identification information of the hub, and pairs the physical device with the hub;
   after the physical device and the hub are installed in the building, causes a third terminal to display a floor plan image of the building showing the arrangement position of the logical device;
   when the arrangement position is designated on the floor plan image via the third terminal, causes the third terminal to display a request for a physical device or a hub installed at the arrangement position; and
   in response to the request, associates the identification information read from the physical device or the hub by the third terminal with the logical device arranged on the floor plan image.

### Appendix 14

The method according to Appendix 13, wherein
the processing circuitry
displays a list of a logical device required to be associated with a physical device, and
when a selection of a logical device from the logical device displayed in the list is received, displays a corresponding position on the floor plan image so as to be distinguishable from a position corresponding to another logical device.

### Appendix 15

The method according to Appendix 13 or 14, wherein
upon receiving a selection of a specific position on the floor plan image, the processing circuitry causes the selected position and a name of a corresponding logical device to be displayed.

### Appendix 16

The method according to any one of Appendixes 13 to 15, wherein
when association between the physical device and the logical device is being executed via a specific third terminal among a plurality of the third terminals, the processing circuitry refrains from allowing execution of processing via another third terminal.

### Appendix 17

The method according to any one of Appendixes 13 to 16, wherein
upon receiving an instruction to verify an operation of an installed physical device, the processing circuitry transmits a signal for driving the physical device to a position at which the physical device is installed.

### Appendix 18

The method according to Appendix 17, wherein
the processing circuitry receives an input of whether or not the installed physical device has been driven, and stores a result.

### Appendix 19

The method according to claim 18, wherein
the processing circuitry manages an unassociated logical device, an associated logical device, a logical device that is associated but has failed in verification, or a logical device that has been verified.

### Appendix 20

The method according to claim 19, wherein
the processing circuitry causes a number of the unassociated logical device, a number of the associated logical device, a number of the logical device that is associated but has failed in the verification, or a number of the logical device that has been verified to be displayed.

1. A system comprising one or more information processing apparatuses, wherein
the one or more information processing apparatuses include processing circuitry, and
the processing circuitry is configured to:
receive, from a first terminal, an input of an arrangement of a logical device and an input of a usage of the logical device on architectural drawing data of a specific building;
register an arrangement position and operation setting of the logical device based on the architectural drawing data with which the arrangement and usage of the logical device are associated;
receive, from a second terminal, identification information of a physical device to be installed in the building and identification information of a hub to be installed in the building, wherein a label that allows identification of the identification information of the physical device is attached to the physical device, and a label that allows identification of the identification information of the hub is attached to the hub;
register the identification information of the physical device and the identification information of the hub, and pair the physical device with the hub;
after the physical device and the hub are installed in the building, cause a third terminal to display a floor plan image of the building showing the arrangement position of the logical device;
when the arrangement position is designated on the floor plan image via the third terminal, cause the third terminal to display a request for a physical device or a hub installed at the arrangement position; and
in response to the request, associate the identification information read from the physical device or the hub by the third terminal with the logical device arranged on the floor plan image.

2. The system according to claim 1, wherein the processing circuitry is further configured to propose an arrangement of the logical device based on a layout of the building.

3. The system according to claim 1, wherein the processing circuitry is further configured to propose a logical device that can be arranged, based on a layout of the building.

4. The system according to claim 1, wherein the processing circuitry is further configured to propose a logical device that can be arranged at a designated position on the architectural drawing data.

5. The system according to claim 1, wherein the processing circuitry is further configured to generate order information for ordering a required physical device, based on the architectural drawing data with which the arrangement and usage of the logical device are associated.

6. The system according to claim 1, wherein
the processing circuitry is further configured to:
display a list of a logical device required to be associated with a physical device, and
when a selection of a logical device from the logical device displayed in the list is received, display a corresponding position on the floor plan image so as to be distinguishable from a position corresponding to another logical device.

7. The system according to claim 1, wherein
the processing circuitry is further configured to, upon receiving a selection of a specific position on the floor plan image, cause the selected position and a name of a corresponding logical device to be displayed.

8. The system according to claim 1, wherein
the processing circuitry is further configured to, when association between the physical device and the logical device is being executed via a specific third terminal among a plurality of the third terminals, refrain from allowing execution of processing via another third terminal.

9. The system according to claim 1, wherein
the processing circuitry is further configured to, upon receiving an instruction to verify an operation of an installed physical device, transmit a signal for driving the physical device to a position at which the physical device is installed.

10. The system according to claim 9, wherein
the processing circuitry is further configured to receive an input of whether or not the installed physical device has been driven, and store a result.

11. The system according to claim 10, wherein
the processing circuitry is further configured to manage an unassociated logical device, an associated logical device, a logical device that is associated but has failed in verification, or a logical device that has been verified.

12. The system according to claim 11, wherein
the processing circuitry is further configured to cause a number of the unassociated logical devices, a number of the associated logical devices, a number of the logical devices that are associated but have failed in the verification, or a number of the logical devices that have been verified to be displayed.

13. A method executed by processing circuitry included in one or more information processing apparatuses in a system including the one or more information processing apparatuses, the method comprising:
receiving, from a first terminal, an input of an arrangement of a logical device and an input of a usage of the logical device on architectural drawing data of a specific building;
registering an arrangement position and operation setting of the logical device based on the architectural drawing data with which the arrangement and usage of the logical device are associated;
receiving, from a second terminal, identification information of a physical device to be installed in the building and identification information of a hub to be installed in the building, wherein a label that allows identification of the identification information of the physical device is attached to the physical device, and a label that allows identification of the identification information of the hub is attached to the hub;
registering the identification information of the physical device and the identification information of the hub, and pairing the physical device with the hub;
after the physical device and the hub are installed in the building, causing a third terminal to display a floor plan image of the building showing the arrangement position of the logical device;
when the arrangement position is designated on the floor plan image via the third terminal, causing the third terminal to display a request for a physical device or a hub installed at the arrangement position; and
in response to the request, associating the identification information read from the physical device or the hub by the third terminal with the logical device arranged on the floor plan image.

14. The method according to claim 13, the method further comprising:
displaying a list of a logical device required to be associated with a physical device, and
when a selection of a logical device from the logical device displayed in the list is received, displaying a corresponding position on the floor plan image so as to be distinguishable from a position corresponding to another logical device.

15. The method according to claim 13,
the method further comprising, upon receiving a selection of a specific position on the floor plan image, causing the selected position and a name of a corresponding logical device to be displayed.

16. The method according to claim 13, the method further comprising, when association between the physical device and the logical device is being executed via a specific third terminal among a plurality of the third terminals, refraining from allowing execution of processing via another third terminal.

17. The method according to claim 13, the method further comprising, upon receiving an instruction to verify an operation of an installed physical device, transmitting a signal for driving the physical device to a position at which the physical device is installed.

18. The method according to claim 17, the method further comprising receiving an input of whether or not the installed physical device has been driven, and storing a result.

19. The method according to claim 18, the method further comprising managing an unassociated logical device, an associated logical device, a logical device that is associated but has failed in verification, or a logical device that has been verified.

20. The method according to claim 19, the method further comprising causing a number of the unassociated logical devices, a number of the associated logical devices, a number of the logical devices that are associated but have failed in the verification, or a number of the logical devices that have been verified to be displayed.
